(19) United States
(12) Patent Application Publication
(10) Pub. No.: US 2026/0067135 A1
(43) Pub. Date: Mar. 5, 2026

(54) DIGITAL PROCESSING CIRCUIT AND RECEIVER

(71) Applicant: SAMSUNG ELECTRONICS CO., LTD., Suwon-si (KR)

(72) Inventors: GARAM CHA, Suwon-si (KR); JUNGHOON CHUN, Suwon-si (KR); SEUNG PARK, Suwon-si (KR)

(73) Assignees: SAMSUNG ELECTRONICS CO., LTD., Suwon-si (KR); RESEARCH & BUSINESS FOUNDATION SUNGKYUNKWAN UNIVERSITY, Suwon-si (KR)

(21) Appl. No.: 19/200,230

(22) Filed: May 6, 2025

(30) Foreign Application Priority Data
Sep. 4, 2024 (KR) 10-2024-0120258

(51) Int. Cl. H04L 25/03; H03M 1/12; H04L 25/49

(52) U.S. Cl. CPC H04L 25/03057; H04L 25/4917; H03M 1/12

(57) ABSTRACT

A digital processing circuit includes a first feed forward equalizer (FFE) circuit configured to equalize a digital signal including a plurality of symbols according to a pulse amplitude modulation (PAM) method and to output a first equalization signal; a second FFE circuit configured to equalize the digital signal and to output a second equalization signal; and a decision feedback equalization (DFE) circuit. The DFE circuit generates a plurality of candidate values using: i) a first equalization signal of a first region associated with a previous symbol, ii) a second region associated with the present symbol and iii) the present symbol. The DFE circuit inputs the symbol value of the previous symbol as a select signal, and selects one of the plurality of candidate values and outputs the value as a symbol value of the present symbol.

### CROSS-REFERENCE TO RELATED APPLICATION(S)

This application claims priority to Korean Patent Application No. 10-2024-0120258 filed on Sep. 4, 2024 in the Korean Intellectual Property Office, the disclosure of which is incorporated by reference herein in its entirety.

### BACKGROUND

Example embodiments of the present disclosure relate to a digital processing circuit including a decision feedback equalizer, and a receiver including a digital processing circuit.

A receiver may use an equalization circuit such as a decision feedback equalization (DFE) to compensate for signal loss due to inter-symbol interference (ISI). Recent receivers may convert received analog signals into multi-channel digital signals by slicing the signals using clock signals having different phases, and may process the digital signals using a plurality of unit DFE circuits.

Due to characteristics of the DFE circuit, an output of a previous unit DFE circuit may be necessary to determine an output of a unit DFE circuit, and accordingly, a plurality of unit DFE circuits may include a chain path. In order to satisfy time constraints for the signal, a structure to minimize delay by simplifying a chain path which requires an output of a previous unit DFE circuit in a plurality of unit DFE circuits has been researched.

### SUMMARY

One or more example embodiments of the present disclosure provide a DFE circuit which may overcome time constraints of a chain path by probabilistically resolving accumulation of delay in the chain path, in addition to simplifying the chain path.

According to aspect of an example embodiment, a digital processing circuit includes: a first feed forward equalizer (FFE) circuit configured to equalize a digital signal including a plurality of symbols according to a pulse amplitude modulation (PAM) method and to output a first equalization signal; a second FFE circuit configured to equalize the digital signal and to output a second equalization signal; and a decision feedback equalization (DFE) circuit, wherein the DFE circuit comprises: a candidate generation circuit configured to determine a first region to which a previous symbol among the plurality of symbols belongs and a second region to which a present symbol among the plurality of symbols belongs by slicing the second equalization signal into a plurality of voltage levels corresponding to symbol values, and to generate two candidate signals by adding at least one signal selected based on the first region among a plurality of weighted signals determined by applying a coefficient to possible values of the previous symbol to the first equalization signal of the present symbol; a slicing circuit configured to generate two slicing values by slicing the two candidate signals with respect to a reference voltage determined based on the second region among a plurality of candidate reference voltages, and to restore the two slicing values to candidate values of the present symbol based on the second region; and a chain multiplexer circuit configured to receive a symbol value of the previous symbol as a select signal, to select one of candidate values of the present symbol and to output the value as a symbol value of the present symbol, and wherein the candidate generation circuit is further configured to: based on the first region being a lowermost region in a range lower than a lowermost voltage level among the plurality of voltage levels, generate the two candidate signals having a same voltage level using a first signal having an uppermost level among the plurality of weighted signals, or based on the first region being an uppermost region having a voltage level higher than an uppermost voltage level among the plurality of voltage levels, generate the two candidate signals having the same voltage level using a second signal having a lowermost voltage level among the plurality of weighted signals.

According to an aspect of an example embodiment, a digital processing circuit includes: a first feed forward equalizer (FFE) circuit configured to equalize a digital signal including a plurality of symbols according to a pulse amplitude modulation (PAM) method and to output a first equalization signal; a second FFE circuit configured to equalize the digital signal and to output a second equalization signal; and an M-tap decision feedback equalization (DFE) circuit configured to use M previous symbols to equalize a present symbol among the plurality of symbols, where M is a natural number, wherein the DFE circuit comprises: a first slicer configured to determine M first regions to which M previous symbols among the plurality of symbols belong and a second region to which the present symbol among the plurality of symbols belongs, respectively, by slicing the second equalization signal into a plurality of voltage levels corresponding to symbol values, respectively; M first multiplexer circuits configured to receive a plurality of weighted signals generated by applying a coefficient corresponding to a corresponding symbol among the M previous symbols to possible values of the corresponding symbol, and to output one or more signals selected based on a corresponding first region among the M first regions as two weighted signals, adders configured to generate 2M candidate signals by adding signals obtained by combining weighted signals output by the M first multiplexer circuits to the first equalization signal of the present symbol; a slicing circuit configured to generate slicing values by slicing the candidate signals by a reference voltage determined based on the second region among a plurality of candidate reference voltages, and to restore the slicing values to candidate values of the present symbol based on the second region; and a chain multiplexer circuit configured to receive symbol values of the M previous symbols as select signals and to output one of the candidate values of the present symbol as a symbol value of the present symbol, and wherein each of the M first multiplexer circuits is further configured to: based on the corresponding first region being a lowermost region in a range lower than a lowermost voltage level among the plurality of voltage levels, generate the two candidate signals using a first signal having an uppermost level among the plurality of weighted signals, or based on the corresponding first region being an uppermost region higher than an uppermost voltage level among the plurality of voltage levels, generate the two candidate signals using a second signal having a lowermost level among the plurality of weighted signals.

According to an aspect of an example embodiment, a receiver includes: an analog-to-digital converter (ADC) circuit configured to generate a digital signal including a plurality of symbols of a received signal modulated according to a pulse amplitude modulation (PAM) method; and a digital processing circuit configured to receive the plurality of symbols and to output symbol values of the plurality of symbols, wherein the digital processing circuit comprises: a first feed forward equalizer (FFE) circuit configured to output a first equalization signal of the plurality of symbols; a second FFE circuit configured to output a second equalization signal of the plurality of symbols; and a decision feedback equalization (DFE) circuit configured to output N symbol values by processing N symbols in parallel among the plurality of symbols, where Nis a natural number, wherein the DFE circuit comprises: a parallel stage including N circuits configured to determine a first region to which a previous symbol among the N symbols belongs and a second region to which a corresponding symbol among the N symbols belongs by slicing the second equalization signal into a plurality of voltage levels corresponding to symbol values, respectively, to generate a plurality of candidate values using the first equalization signal of the first region, the second region and the corresponding symbol; and a chain path including N chain multiplexer circuits configured to receive a symbol value of the previous symbol as a select signal, and to output one of the plurality of candidate values as a symbol value of the corresponding symbol, and wherein each of the N circuits is configured to, based on the first region or the second region being a lowermost region in a range lower than a lowermost voltage level among the plurality of voltage levels or an uppermost region higher than an uppermost voltage level among the plurality of voltage levels, input the plurality of candidate values having the same value to a corresponding multiplexer circuit among the N multiplexer circuits.

### BRIEF DESCRIPTION OF THE DRAWINGS

The above and other aspects, features, and advantages of the present disclosure will be more clearly understood from the following detailed description, taken in combination with the accompanying drawings, in which:

FIG. 1 is a diagram illustrating a data transmission and reception system using a serializer/deserializer (SERDES) according to an example embodiment of the present disclosure;

FIG. 2A is a diagram illustrating a feed forward equalization (FFE) circuit according to an example embodiment of the present disclosure;

FIG. 2B is a diagram illustrating a decision feedback equalization (DFE) circuit according to an example embodiment of the present disclosure;

FIG. 3 is a diagram illustrating an example of a multi-channel DFE circuit according to an example embodiment of the present disclosure;

FIG. 4 is a diagram illustrating an example of a loop-unrolled DFE circuit according to an example embodiment of the present disclosure;

FIG. 5 is a diagram illustrating an example of a partially unrolled DFE circuit according to an example embodiment of the present disclosure;

FIG. 6 is a diagram illustrating accumulated delay in a chain path of a partially unrolled DFE circuit according to an example embodiment of the present disclosure;

FIG. 7 is a diagram illustrating an example of a 2:1 multiplexer circuit according to an example embodiment of the present disclosure;

FIG. 8 is a diagram illustrating a receiver according to an example embodiment of the present disclosure;

FIG. 9 is a diagram illustrating a unit DFE circuit according to an example embodiment of the present disclosure;

FIGS. 10A and 10B are diagrams illustrating operation of a candidate generation circuit illustrated in FIG. 9;

FIGS. 11A and 11B are diagrams illustrating operation of second slicers illustrated in FIG. 9;

FIGS. 12A and 12B are diagrams illustrating operation of restoration circuits illustrated in FIG. 9;

FIGS. 13A and 13B are diagrams illustrating reliability of a DFE circuit according to an example embodiment of the present disclosure; and

FIG. 14 is a diagram illustrating a unit DFE circuit according to an example embodiment of the present disclosure.

### DETAILED DESCRIPTION

Hereinafter, example embodiments of the present disclosure will be described as below with reference to the accompanying drawings.

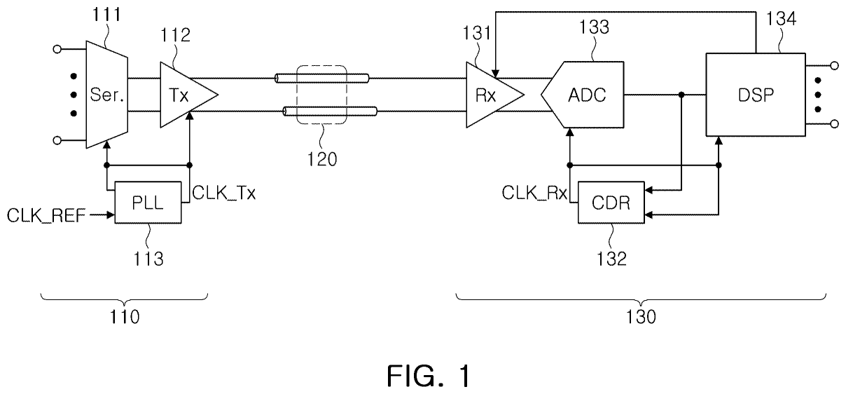

FIG. 1 is a diagram illustrating a data transmission and reception system using a serializer/deserializer (SERDES) according to an example embodiment.

A SERDES may be a functional block frequently used to transmit high-speed data through a channel. The SERDES block may convert parallel data to serial data or vice versa, and may be generally used to transmit parallel data through a single line or differential pair to reduce the number of input/output (I/O) pins and interconnections.

A data transmission and reception system 100 using SERDES may include a transmitter 110, a channel 120, and a receiver 130.

The transmitter 110 may include a serializer 111, a transmission terminal 112, and a phase locked loop (PLL) circuit 113.

The serializer 111 may convert a parallel data signal into a serial data signal, and may provide a serial data signal to the transmission terminal 112. The transmission terminal 112 may include a driver, and the driver may amplify a serial data signal and may output a differential signal to the channel 120. In an example embodiment, the transmission terminal 112 may perform equalization to improve signal integrity of the transmitter 110. The PLL circuit 113 may provide a transmission clock CLK_Tx to the serializer 111 and the transmission terminal 112. For example, the PLL circuit 113 may receive a reference clock CLK_REF and may output a transmission clock CLK_Tx having a constant frequency and phase.

The receiver 130 may restore a differential signal of the serial data received from channel 120 and may convert the serial data into parallel data. The receiver 130 may include a reception terminal 131, a clock data recovery (CDR) circuit 132, an analog-to-digital converter (ADC) circuit 133, and a digital signal processor (DSP) circuit 134.

The reception terminal 131 may receive a differential signal from the channel 120 and may amplify the received differential signal. The reception terminal 131 may perform equalization of the differential signal. For example, the reception terminal 131 may include a continuous time linear equalization (CTLE) circuit and a variable gain amplifier (VGA) circuit.

The CDR circuit 132 may receive a differential signal, may restore a clock using the differential signal, and may output the restored clock as the reception clock CLK_Rx. The ADC circuit 133 may sample the differential signal using the reception clock CLK_Rx, and may convert the sampled signal into a digital signal. The CDR circuit 132 may be implemented using hardware components such as processor, Boolean hardware gates, transistors, resistors, capacitor, inductors and operational amplifiers and implemented using software.

In an example embodiment, the reception clock CLK_Rx may be a multi-phase clock including N number of clock signals having different phases. The ADC circuit 133 may sample a differential signal using the N number of clock signals (N is a natural number).

The DSP circuit 134 may generate N-channel parallel data signals by sampling a digital signal of serial data using N number of clock signals included in the multi-phase clock. The DSP circuit 134 may perform equalization of the parallel data signals. For example, the DSP circuit 134 may include a feed forward equalization (FFE) circuit and a decision feedback equalization (DFE) circuit to perform equalization of the parallel data signals.

When each of the parallel data signals in the DSP circuit 134 may be equalized in parallel, the high-speed signal received from the channel 120 may be processed effectively. Since the symbol value of a (k−1)th symbol needs to be determined in order to determine a symbol value of a kth symbol among symbols included in the parallel data signals due to characteristics of the DFE circuit, the DFE circuit may include a chain path (k is a natural number).

As the sampling rate increases, time constraints for processing parallel data signals have been stricter. In order to satisfy the time constraint for a signal, a structure to reduce delay by simplifying the chain path requiring the symbol value of the previous symbol in the DFE circuit has been researched.

For example, the DFE circuit may interleave a stage calculating the candidate values of the present symbol value predicted according to the possible previous symbol values for each of the parallel data signals, and may perform only an operation of selecting one of the candidate values by receiving the previous symbol value in the chain path. The chain path of a DFE circuit may include a multiplexer chain in which a plurality of multiplexer circuits are connected. However, the multiplexer circuit may also have an intrinsic delay, and there may be a limitation in reducing the intrinsic delay so as to comply with the strict time constraint.

According to an example embodiment, a structure of a DFE circuit which may reduce the accumulated delay of the chain path in which a plurality of multiplexers are connected based on characteristics of the multiplexer circuit and may statistically overcome the time constraint may be suggested.

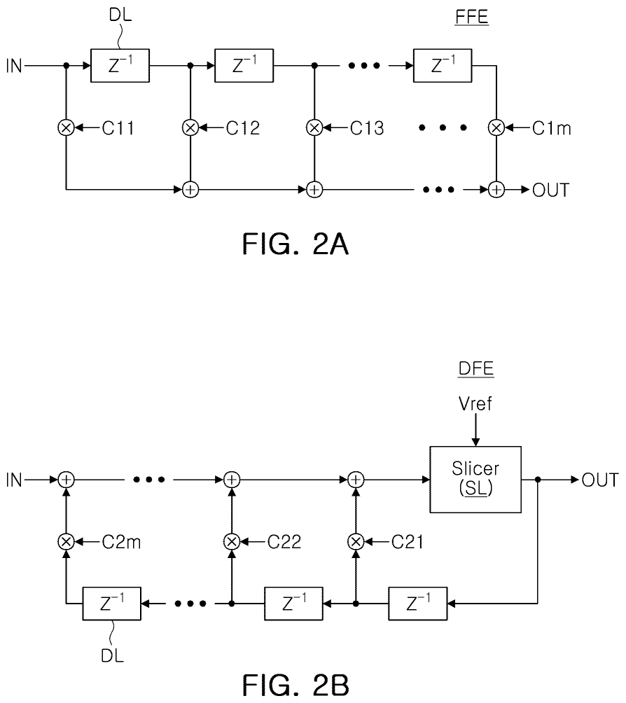

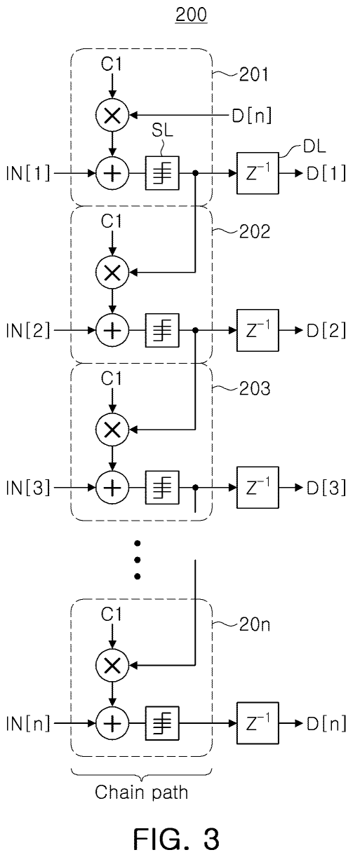

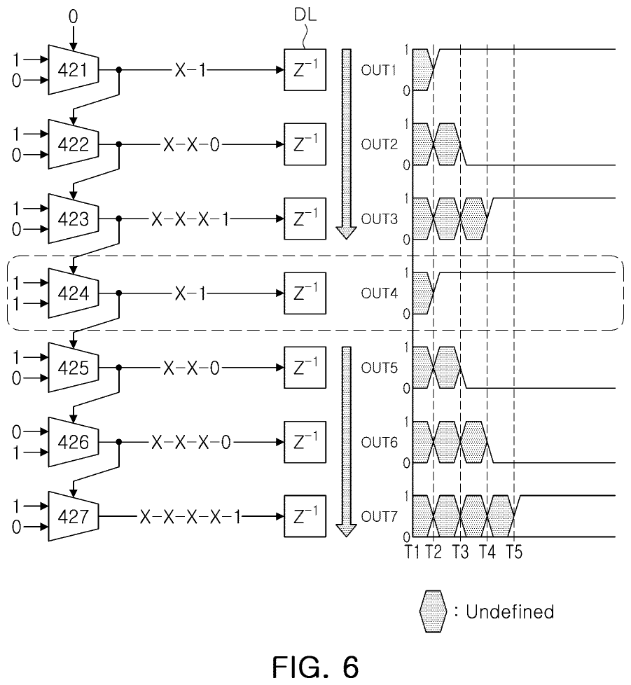

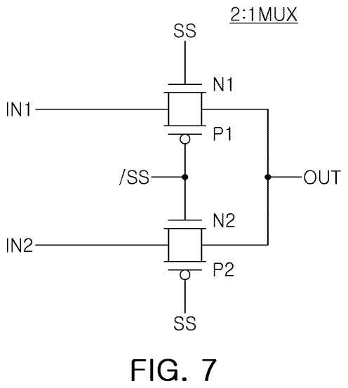

Hereinafter, an FFE circuit and a DFE circuit will be described with reference to FIG. 2A and FIG. 3B, and examples of DFE circuits having various chain paths will be described with reference to FIG. 3 to FIG. 5. The accumulated delay of the chain path may be described in detail with reference to FIG. 6 and FIG. 7. The FFE circuit and DFE circuit may be implemented using hardware components such as flip-flops, registers, processor, Boolean hardware gates, transistors, resistors, capacitors, inductors and operational amplifiers and implemented using software.

FIG. 2A is a diagram illustrating a feed forward equalization (FFE) circuit according to an example embodiment.

An equalizer may refer to a device for improving quality of a signal by compensating for signal distortion caused by inter-symbol interference (ISI). For example, the equalizer may include an FFE determining a value of a present symbol based on a weighted sum of a present symbol and previous symbols which may interfere with the present symbol, and a DFE determining the value of the present symbol by feeding back the determination results for the present symbol and the previous symbols.

Referring to FIG. 2A, the FFE circuit may include a plurality of delay elements DL, a plurality of multipliers, and a plurality of adders. The plurality of delay elements DL may delay an input signal IN by a predetermined time period, for example, one cycle of input data. The plurality of delay elements DL may be connected to each other in a cascade form. For example, when an (m−1) number of delay elements DL are connected, a one cycle delayed signal, a two cycle delayed signal, . . . , a (m−1) cycle

signal of the input signal IN may be generated in the FFE circuit (m is a natural number).

By multipliers, a plurality of FFE coefficients C11, C12, C13, . . . , C1m may be reflected in an input signal IN and a delay signals. For example, the input signal IN may be multiplied by the first FFE coefficient C11, the one cycle delayed signal may be multiplied by the second FFE coefficient C12, the two cycle delayed signal may be multiplied by the third FFE coefficient C13, and the (m−1) cycle delayed signal may be multiplied by the mth FFE coefficient C1m. The signals in which the plurality of FFE coefficients are reflected may be added together by adders and may be output as the output signal OUT.

The FFE circuit illustrated in FIG. 2A may be an FFE circuit having an M-tap structure. The number of plurality of delay elements DL may be varied depending on the number of taps of the FFE circuit.

Referring to FIG. 2B, the DFE circuit may include a plurality of delay elements DL, a slicer SL, a plurality of multipliers, and a plurality of adders. The slicer SL may sample a signal in which the received signal IN and the previous determination results are reflected based on the reference voltage Vref, and may output the sampling result as an output signal OUT.

The plurality of delay elements DL may delay the output signal OUT by a predetermined time period, for example, one cycle of the input data. The plurality of delay elements DL may be connected in a cascade form. For example, when an M number of delay elements DL are connected, a one cycle delayed signal, a two cycle delayed signal, . . . , an m cycle delayed signal of the output signal OUT may be generated.

By the multipliers, a plurality of DFE coefficients C21, C22, . . . , C2m may be reflected in the delay signals of the output signal OUT. For example, the one cycle delayed signal may be multiplied by the first DFE coefficient C21, the two cycle delayed signal may be multiplied by the second DFE coefficient C22, and the m cycle delayed signal may be multiplied by the m-th DFE coefficient C2m. The delay signals in which the input signal IN and the plurality of DFE coefficients C21, C22, . . . , C2m are reflected may be added by the adders and may be sampled by the slicer SL, and the sampled signal may be output as the output signal OUT.

The DFE circuit illustrated in FIG. 2B may be a DFE circuit having an M-tap structure. The number of plurality of delay elements DL may be varied depending on the number of taps of the DFE circuit.

The FFE circuit in FIG. 2A and the DFE circuit in FIG. 2B may be configured as circuits each configured to equalize the input signal IN of a single channel and outputting the output signal OUT of a single channel. A circuit for equalizing N-bit parallel data signals, such as the DSP circuit 134 described with reference to FIG. 1, may include a multi-channel DFE circuit.

FIG. 3 is a diagram illustrating an example of a multi-channel DFE circuit according to an example embodiment.

The multi-channel DFE circuit 200 in FIG. 3 may equalize input signals IN[1]-IN[n] inputted as N number of channels and may determine values of the 1st to nth symbols, and may output symbol values D[1]-D[n] as N number of channels.

In the example in FIG. 3, the input signals IN[1]-IN[n] may be signals modulated according to a pulse amplitude modulation (PAM)-4 method. The multi-channel DFE circuit 200 may be configured as a DFE circuit having a 1-tap structure.

The multi-channel DFE circuit 200 may include a plurality of unit DFE circuits 201, 202, 203, . . . , 20n: 201-20n configured to equalize data signals inputted to each channel and to output a symbol value. For example, the second unit DFE circuit 202 may output the second symbol value D[2] based on the second input signal (IN[2]) and the symbol value of the previous signal. Specifically, the second unit DFE circuit 202 of the 1-tap structure equalizing the PAM-4 signal may add the value obtained by multiplying the first symbol value D[1] by the coefficient C1 to the first input signal IN[1], may sample the added signal using a slicer SL having three reference voltages, and may output the sampling result as the second symbol value D[2]. In example embodiments, a delay element DL may be further included to match operation timings between the unit DFE circuits.

In order for the second unit DFE circuit 202 to determine the second symbol value D[2], the first symbol value D[1] may need to be determined. Similarly, the third unit DFE circuit 203 may need the second symbol value D[2] to determine the third symbol value D[3], and the nth unit DFE circuit 20n may need the (n−1)th symbol value to determine the nth symbol value D[n]. The nth symbol value D[n] may be input to the first unit DFE circuit 201 to determine the first symbol value D[1] of the subsequent cycle.

Accordingly, N number of unit DFE circuits 201-20n may operate in order. In order for N number of input signals IN[1]-IN[n] sampled using multiple clock signals to be processed without delay, operation of N number of unit DFE circuits 201-20n may need to be completed in a 1 clock cycle. That is, a multiplier, an adder, and operation of a slicer included in a unit DFE circuit may need to be completed in a (1/N) clock cycle. As the sampling rate increases and the clock cycle shortens, it may be difficult to complete operation of a unit DFE circuit in the (1/N) cycle of the clock.

In order to satisfy the time constraint for the signal, a structure to reduce delay is by simplifying the chain path of the DFE circuit has been studied.

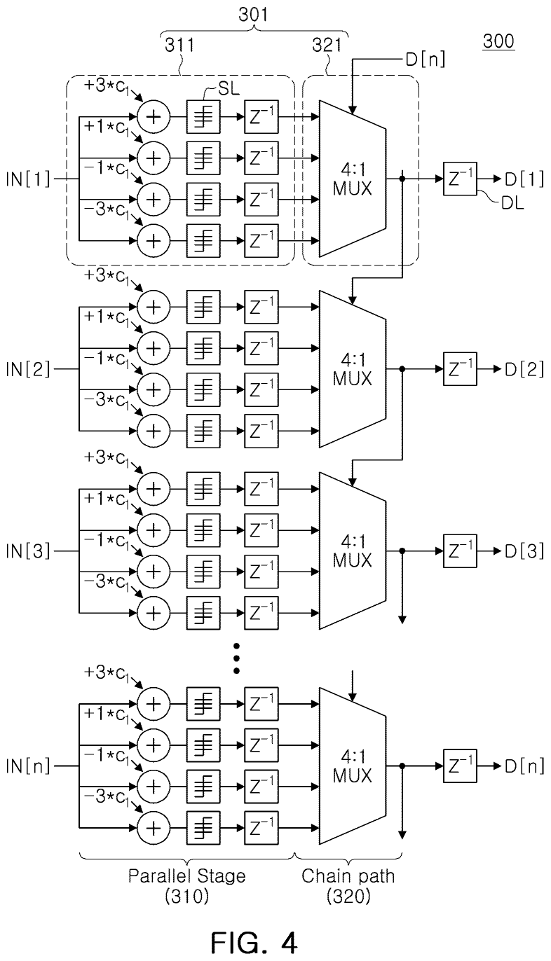

FIG. 4 is a diagram illustrating an example of a loop-unrolled DFE circuit according to an example embodiment.

A loop-unrolled DFE circuit 300 in FIG. 4 may equalize input signals IN[1]-IN[n] inputted as N number of channels, similarly to the multi-channel DFE circuit 200 in FIG. 3, and may output symbol values D[1]-D[n] as N number of channels. The input signals IN[1]-IN[n] may be signals modulated according to the PAM-4 method. The multi-channel DFE circuit 300 may be a DFE circuit having a 1-tap structure.

The loop-unrolled DFE circuit 300 may include a plurality of unit DFE circuits. For example, FIG. 4 may illustrate a first unit DFE circuit 301 outputting the first symbol value D[1] when the first input signal IN[1] is inputted.

Each of the unit DFE circuits may include a candidate generation circuit determining candidate values of the present symbol value based on possible values of the previous symbol, and a multiplexer circuit outputting one of the candidate values as a symbol value based on the determined previous symbol value. For example, the first unit DFE circuit 301 may include the first candidate generation circuit 311 and the first multiplexer circuit 321.

The first candidate generation circuit 311 may generate sum signals by multiplying each of the possible values of the previous symbol by a coefficient and adding each of the values to the first input signal IN[1], and may sample each of the sum signals using a slicer SL having three reference voltages, and may output the sampling results to the first multiplexer circuit 321.

For example, when the input signal is a PAM-4 signal, each of the symbols may have one of four symbol values. In the example in FIG. 4, four symbol values may correspond to binary data “00,” “01,” “10,” “11,” and the data may be normalized to voltage levels of “−3,” “−1,” “+1” and “+3,” respectively.

The first candidate generation circuit 311 may compensate for influence of the nth symbol value D[n] on the first symbol in each case in which the nth symbol value D[n] is “00,” “01,” “10,” “11,” and may determine the candidate values which the first symbol may have. For example, the candidate value when the nth symbol value D[n] is “00” may be generated by adding “+3*C1” to the input signal IN[1]. Similarly, in each case in which the nth symbol value D[n] is “01,” “10” and “11,” the candidate value may be generated by adding “+1*C1,” “−1*C1” and “−3*C1” to the input signal IN[1]. The first candidate generation circuit 311 may determine the candidate values before the nth symbol value D[n] is determined.

When the nth symbol value D[n] is determined, the first multiplexer circuit 321 may select one of the candidate values and may output the selected value as the first symbol value D[1]. For example, when the nth symbol value D[n] is determined as “11,” the candidate value having “−3*C1” added to the input signal IN[1] among the four candidate values may be output. The first multiplexer circuit 321 may be implemented as a 4:1 multiplexer circuit.

The loop-unrolled DFE circuit 300 may include a parallel stage 310 including a plurality of candidate generation circuits, and a chain path 320 including a plurality of multiplexer circuits. Since each of the candidate generation circuits of the parallel stage 310 does not require a previous symbol value, the circuit may be interleaved.

The multiplexer circuits included in the chain path 320 may operate in order based on the previous symbol value. Since the chain path 320 is difficult to be interleaved, the path may be a critical path having a significant impact on determining the processing time of the loop-unrolled DFE circuit 300. The chain path 320 may be simplified as compared to the channel path of the multi-channel DFE circuit 200 described with reference to FIG. 3. However, it may be difficult to reduce the intrinsic delay of the 4:1 multiplexer circuit to within a (1/N) cycle of the clock.

In order to reduce the processing time of the chain path 320 having 4:1 multiplexer circuits, a pipelining multiplexer structure in which multiplexer circuits are grouped into several groups and multiplexers are pipelined by group has been suggested. A look-ahead multiplexer structure in which candidate values are determined by considering possible values of the (k−1)th symbol and also possible values of the (k−2)th symbol to determine the value of the kth symbol, and the value of the kth symbol may be output when the values of the (k−2)th symbol are determined has been suggested.

In order for multiplexers to be pipelined by group, symbol values output by multiplexers of the preceding group need to be delayed, and accordingly, signal delay may increase. In order for a look-ahead multiplexer structure to be implemented, the number of multiplexer circuits required per unit DFE circuit may increase exponentially depending on how many preceding symbol values are used to determine the symbol value.

A partially unrolled DFE circuit structure in which the multiplexer circuit included in the chain path may be further simplified into a 2:1 multiplexer circuit by roughly predicting the value of the previous symbol and reducing the number of candidate values has been suggested.

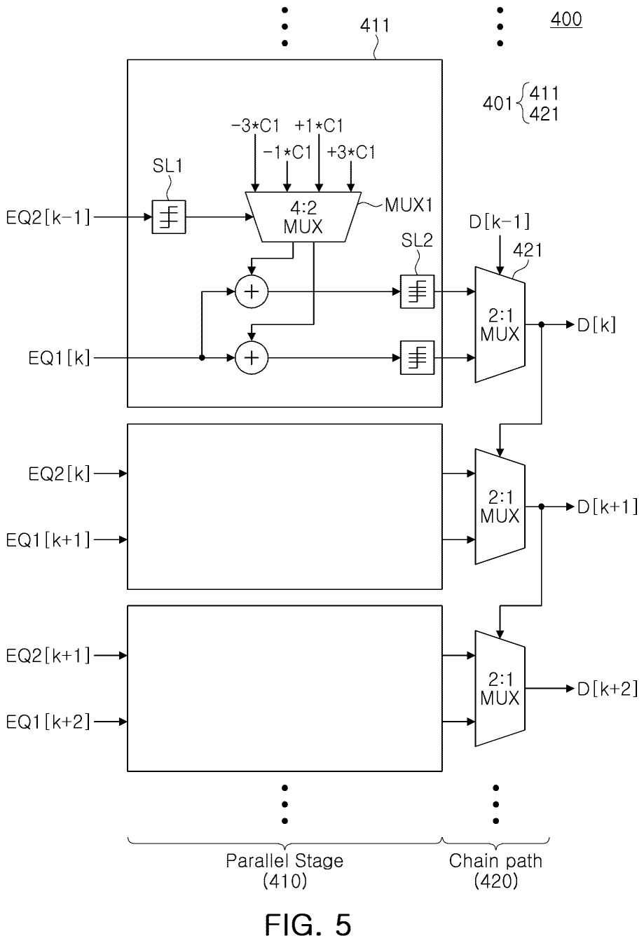

FIG. 5 is a diagram illustrating an example of a partially unrolled DFE circuit according to an example embodiment.

Similarly to the loop-unrolled DFE circuit 300 in FIG. 4, the partially unrolled DFE circuit 400 in FIG. 5 may equalize input signals input to N number of channels, and may output symbol values D[1]-D[n] to the N number of channels. The input signals may be signals modulated according to the PAM-4 method. The partially unrolled DFE circuit 400 may be a DFE circuit having a 1-tap structure.

The partially unrolled DFE circuit 400 may include a plurality of unit DFE circuits. For example, FIG. 4 may illustrate a first unit DFE circuit 401 outputting a kth symbol value D[k]. The first unit DFE circuit 401 may include a first candidate generation circuit 411 and a chain multiplexer circuit 421. A plurality of candidate generation circuits may form a parallel stage 410, and a plurality of chain multiplexer circuits may form a chain path 420.

The first candidate generation circuit 411 may receive signals from the first FFE circuit and the second FFE circuit. The first FFE circuit and the second FFE circuit may have structures such as the examples described with reference to FIG. 2A. The second FFE circuit may be configured to have a smaller number of taps than the first FFE circuit. The second FFE circuit may have lower accuracy than the first FFE circuit, and may equalize a signal more swiftly than the first FFE circuit.

The first FFE circuit may output the first equalization signal EQ1[k] by equalizing the kth input signal, and the second FFE circuit may output the second equalization signal EQ2[k−1] by equalizing the (k−1)th input signal.

The second equalization signal EQ2[k−1] may roughly determine the range of the symbol value before the symbol value D[k−1] of the previous symbol is determined. Since the second FFE circuit has a smaller number of taps than the first FFE circuit, the approximate range of the symbol value may be swiftly determined. The first candidate generation circuit 411 may reduce the number of candidate values to be selected based on the approximate range of the symbol value based on the determined symbol value D[k−1].

The first candidate generation circuit 411 may include the first slicer SL1, the first multiplexer circuit MUX1, the second slicer SL2, and adders. The first slicer SL1 may roughly determine the range of symbol values based on the second equalization signal EQ2[k−1]. For example, when the input signal is a PAM-4 signal, by slicing the second equalization signal EQ2[k−1] using two reference voltages, it may determine whether the symbol value of the previous symbol is “00” or “01,” “01” or “10,” or “10” or “11.”

The first multiplexer circuit MUX1 may select and output two weighted signals according to the range of symbol values of the previous symbol among the weighted signals that apply coefficient C1 to possible values of the previous symbol. For example, four symbol values “00,” “01,” “10” and “11” may be normalized to levels of “−3,” “−1,” “+1” and “+3.” The first multiplexer circuit MUX1 may input weighted signals corresponding to cases in which the (k−1)th symbol value D[k−1] is “00,” “01,” “10” and “11,” respectively. When the symbol value range of the previous symbol is “00” to “01,” the first multiplexer circuit MUX1 may output “+3*C1” and “+1*C1,” which are weighted signals to compensate for influence of the (k−1)th symbol value D[k−1] “00” and “01” among the weighted signals.

Each of the adders may output the values obtained by adding the weighted signals output to the first equalization signal EQ1[k] to the second slicers SL2. The second slicers SL2 may sample the summed signals using three reference voltages and may output the sampling results as candidate values. For example, the first candidate generation circuit 411 may reduce the number of candidate values to be selected in the multiplexer circuit 421 from four to two using the second equalization signal EQ2[k−1].

The chain multiplexer circuit 421 may be a 2:1 multiplexer circuit selecting one of the two candidate values and outputting the value as the kth symbol value D[k] when the determined (k−1)th symbol value D[k−1] is input.

A partially unrolled DFE circuit 400 may include a parallel stage 410 including a plurality of candidate generation circuits, and a chain path 420 including a plurality of chain multiplexer circuits. The intrinsic delay of the 2:1 multiplexer circuit may be smaller than the intrinsic delay of the 4:1 multiplexer circuit. Accordingly, an operation time of the chain path 420 may be shorter than an operation time of the chain path 320 described with reference to FIG. 4. However, it may still be difficult to reduce the intrinsic delay of the 2:1 multiplexer circuit to within a (1/N) cycle of a clock.

According to an example embodiment, a structure of a DFE circuit reducing the accumulated delay of a chain path in which a plurality of multiplexers are connected based on characteristics of the multiplexer circuit and statistically overcoming the time constraint may be suggested.

FIG. 6 is a diagram illustrating accumulated delay in a chain path of a partially unrolled DFE circuit according to an example embodiment.

FIG. 6 may illustrate a chain path in which seven 2:1 multiplexer circuits 421-427 are connected, and timings of output signals OUT1-OUT7 of the 2:1 multiplexer circuits 421-427.

In the chain path in FIG. 6, values of two input signals input to the first multiplexer circuit 421 may be output in response to determination of the output signal of the previous multiplexer circuit. For example, when two input signals of “1” and “0” are input to the first multiplexer circuit 421 and the output signal of the previous multiplexer circuit is undefined, the first output signal OUT1 of the first multiplexer 421 may not be determined as “1” or “0” and may be in an undefined state. When an input signal is input at a first time point T1, and the output signal of the previous multiplexer circuit may be determined at the first time point T1, the value of the first output signal OUT1 may be determined as “1” from the second time point T2 after a time corresponding to the intrinsic delay of the first multiplexer circuit 421 has elapsed. The value of the first output signal OUT1 may be undefined until the second time point T2.

When input signals of “1” and “0” are input to the second multiplexer circuit 422, the value of the second output signal OUT2 of the second multiplexer circuit 422 may be determined after the value of the first output signal OUT1 is determined. The value of the first output signal OUT1 may be determined at the second time point T2, and the value of the second output signal OUT2 may be determined as “0” from the third time point T3 after a time corresponding to the intrinsic delay of the second multiplexer circuit 422 has elapsed.

The value of the third output signal OUT3 based on the two input signals of “1” and “0” input to the third multiplexer circuit 423 may be determined as “1” from the fourth time point T4, which is a time corresponding to the intrinsic delay of the third multiplexer circuit 423 has elapsed after the value of the second output signal OUT2 is determined.

Due to the structure requiring the output value of the previous multiplexer circuit to determine the output value of each multiplexer circuit in the chain path, the accumulated delay may occur in the chain path.

For example, the values of the input signals of the first to third multiplexer circuits 421-423 may be determined at a time interval corresponding to a (1/N) cycle of the clock. When the intrinsic delay of the multiplexer circuit is greater than the (1/N) cycle of the clock, a delay may occur between the timing at which the input signal of the multiplexer circuit is input and the timing at which the output signal of the previous multiplexer circuit is determined. Each time the computation of the subsequent multiplexer circuit is performed, a delay may accumulate between the timing at which the input signal is input and the timing at which the output signal of the previous multiplexer circuit is determined.

The accumulated delay may be resolved due to characteristics of the multiplexer circuit.

In the example in FIG. 6, differently from the input signals having different values input to the first to third multiplexer circuits 421-423, input signals having the same value may be input to the fourth multiplexer circuit 424.

When the input signals of a multiplexer circuit have the same value, the output signal value of the multiplexer circuit may be determined regardless of the value of the output signal of the previous multiplexer circuit.

FIG. 7 is a diagram illustrating an example of a 2:1 multiplexer circuit according to an example embodiment.

A 2:1 multiplexer circuit 2:1MUX may include a plurality of NMOS transistors N1, N2 and PMOS transistors P1, P2. The 2:1 multiplexer circuit 2:1MUX may select one of two input signals IN1 and IN2 according to a logic level of the select signal SS and may output the signal as an output signal OUT.

The first active regions and the second active regions of the first NMOS transistor N1 and the first PMOS transistor P1 may be connected to each other. The first active regions may be connected to the first input signal IN1, and the second active regions may be connected to the output signal OUT. A gate of the first NMOS transistor N1 may be connected to a select signal SS, and a gate of the first PMOS transistor P1 may be connected to a complementary select signal/SS.

The first active regions and the second active regions of the second NMOS transistor N2 and the second PMOS transistor P2 may be connected to each other. The first active regions may be connected to the second input signal IN2, and the second active regions may be connected to the output signal OUT. A gate of the second NMOS transistor N2 may be connected to a complementary select signal/SS, and a gate of the second PMOS transistor P2 may be connected to a select signal SS.

When the select signal SS has a “1” value and the complementary select signal/SS has a “0” value, the first NMOS transistor N1 and the first PMOS transistor P1 may be turned on, and the second NMOS transistor N2 and the second PMOS transistor P2 are turned off, such that the first input signal IN1 may be output as the output signal OUT.

When the select signal SS has a “0” value and the complementary select signal/SS has a “1” value, the first NMOS transistor N1 and the first PMOS transistor P1 may be turned off, and the second NMOS transistor N2 and the second PMOS transistor P2 may be turned on, such that the second input signal IN2 may be output.

When the first input signal IN1 and the second input signal IN2 have different values, and when the select signal SS has an unstable value, the turned-on state of the transistors may change, and the output signal OUT may have an unstable value.

When the first input signal IN1 and the second input signal IN2 have the same value, and even when the select signal SS has an unstable value and the turned-on state of the transistors changes according to the select signal SS, at least one transistor may be in the turned-on state. Accordingly, the output signal OUT may be stabilized to the same value of the first and second input signals IN1 and IN2 before the select signal SS becomes stable.

Referring back to FIG. 6, when two input signals of “1” and “1” are input to the fourth multiplexer circuit 424, the value of the output signal OUT4 of the fourth multiplexer circuit 424 may be stabilized to “1” even before the value of the third multiplexer circuit 423 is determined. For example, when an input signal is input at the first time point T1, the value of the first output signal OUT1 may be determined to be “1” from the second time point T2 after a time corresponding to the intrinsic delay of the first multiplexer circuit 421 has elapsed. In other words, the delay accumulated in the paths of the first to third multiplexer circuits 421-423 may be resolved in the fourth multiplexer circuit 424.

The input signals of the fifth to seventh multiplexer circuits 425, 426, and 427 may be different. The value of the output signal of the fifth multiplexer circuit 425 may be determined after the value of the output signal of the fourth multiplexer circuit 424 is determined, the value of the output signal of the sixth multiplexer circuit 426 may be determined after the value of the output signal of the fifth multiplexer circuit 425 is determined, and the value of the output signal of the seventh multiplexer circuit 427 may be determined after the value of the output signal of the sixth multiplexer circuit 426 is determined. The accumulated delays may occur in the paths of the fifth to seventh multiplexer circuits 425, 426, and 427. The first to third multiplexer circuits 421-423 and the fourth to sixth multiplexer circuits 424-426 may operate simultaneously.

When the accumulated delays may be resolved at appropriate time points in the chain path, a plurality of 2:1 multiplexer circuits included in the chain path may operate simultaneously. Accordingly, even though the intrinsic delay of the 2:1 multiplexer circuit is greater than a (1/N) cycle of the clock, the time constraint may be overcome in a chain path having N number of 2:1 multiplexer circuits.

For example, it may be assumed that the chain path has 32 2:1 multiplexer circuits, and 22 2:1 multiplexer circuits may operate in order in one clock cycle due to the intrinsic delay of the 2:1 multiplexer circuits. When the accumulated delay may be resolved whenever operation of the multiplexer circuits within 22 in the chain path is completed, operation of 32 2:1 multiplexer circuits may be completed in one clock cycle.

When the chain path is applied to the DFE circuit of the receiver, and the probability that the delay accumulates in the multiplexer circuits exceeding 22 may be significantly lowered than the target bit error rate (BER) of the receiver, the DFE circuit of the receiver may be statistically reliable.

According to an example embodiment, by increasing the probability that input signals input to the multiplexer circuit in each unit DFE circuit have the same value, the probability that delay accumulates in the multiplexer circuits may be reduced, and a statistically reliable DFE circuit and receiver may be provided.

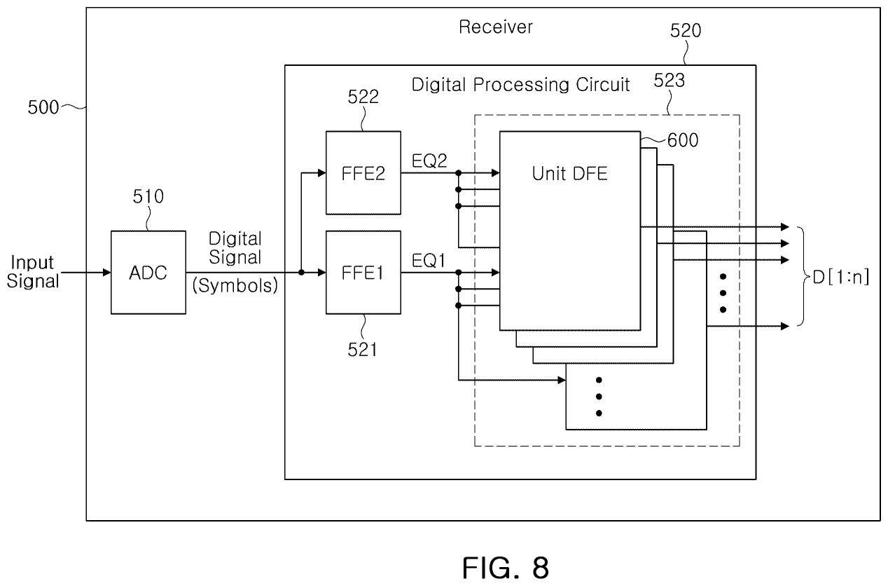

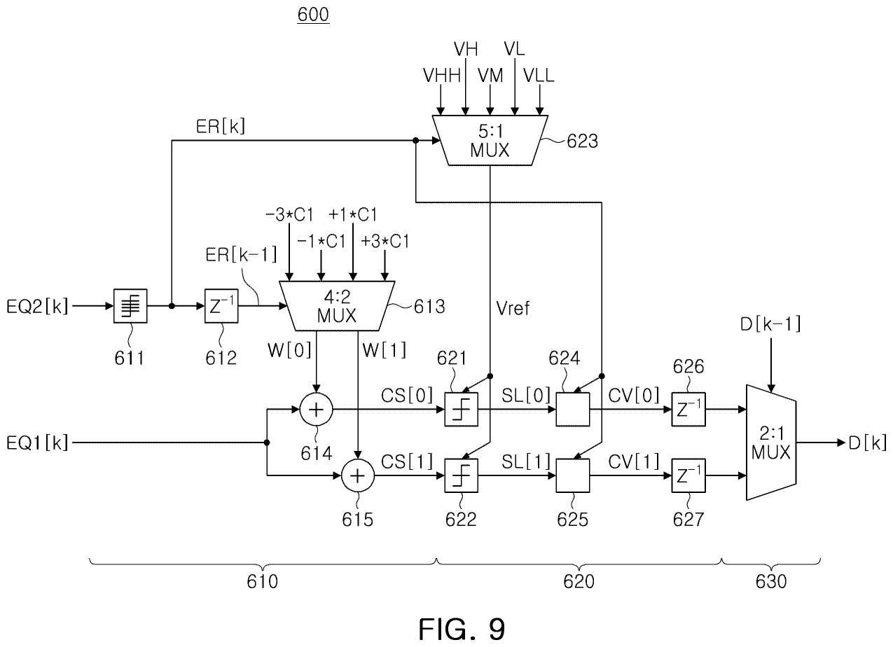

Hereinafter, a structure of a receiver according to an example embodiment will be described with reference to FIG. 8, and a unit DFE circuit according to an example embodiment may be described in detail with reference to FIGS. 9 to 14.

FIG. 8 is a diagram illustrating a receiver according to an example embodiment.

Referring to FIG. 8, a receiver 500 may include an ADC circuit 510 and a digital processing circuit 520. The ADC circuit 510 may sample an input signal of serial data and may convert the sampled signal into a digital signal, similarly to the ADC circuit 133 described with reference to FIG. 1. The digital signal may include a plurality of symbols which may be sequential in time.

A digital processing circuit 520 may receive a plurality of symbols and output symbol values D[1:n] as a data signal by equalizing the received symbols.

The digital processing circuit 520 may include a first FFE circuit 521, a second FFE circuit 522, and a DFE circuit 523. The first FFE circuit 521 and the second FFE circuit 522 may have structures as described with reference to FIG. 2A. The second FFE circuit 522 may be a circuit having a smaller number of taps than the first FFE circuit 521.

The first FFE circuit 521 may receive a plurality of symbols from an ADC circuit 510 and may output a first equalization signal EQ1 to the DFE circuit 523 by equalizing the plurality of symbols. The second FFE circuit 522 may receive a plurality of symbols from the ADC circuit 510 and may output the second equalization signal EQ2 to the DFE circuit 523 by equalizing the plurality of symbols. The second FFE circuit 522 may have lower accuracy than the first FFE circuit 521, and may output the equalization signal more swiftly.

The DFE circuit 523 may include a plurality of unit DFE circuits 600. As described with reference to FIG. 1, digital signals may be parallelized into N-channel signals in the DFE circuit 523, and symbol values D[1:n] of the N-channel signals may be output as data signals.

The equalization signals EQ1 and EQ2 output by the first and second FFE circuits 521 and 522 may be input to the plurality of unit DFE circuits 600. A plurality of unit DFE circuits 600 may process N number of symbols received in a 1 clock cycle. Each of the plurality of unit DFE circuits 600 may include a candidate decision circuit, a slicing circuit, and a multiplexer circuit. The candidate decision circuits and the slicing circuits of the plurality of unit DFE circuits 600 may form a parallel stage, and the multiplexer circuits may form a chain path.

According to an example embodiment, the candidate decision circuit and the slicing circuit of the unit DFE circuit 600 may have a structure for increasing the probability that candidate values input to the multiplexer circuit have the same value.

FIG. 9 is a diagram illustrating a unit DFE circuit according to an example embodiment.

The unit DFE circuit 600 may include a candidate decision circuit 610, a slicing circuit 620, and a chain multiplexer circuit 630. The candidate decision circuits and the slicing circuits of the plurality of unit DFE circuits 600 described with reference to FIG. 8 may form a parallel stage, and the chain multiplexer circuits 630 may form a chain path.

The unit DFE circuit 600 in FIG. 9 may be a 1-tap DFE circuit determining a symbol value D[k] of a kth symbol among N number of symbols using a symbol value D[k−1] of a (k−1)th symbol. Each of N number of symbols may be symbols according to PAM-4.

The candidate decision circuit 610 may receive a first equalization signal EQ1 from the first FFE circuit 521 described with reference to FIG. 8, and a second equalization signal EQ2 from the second FFE circuit 522. The candidate decision circuit 610 may include a first slicer 611, a first delay element 612, a first multiplexer circuit 613, and adders 614 and 615.

The first slicer 611 may generate a first region value ER[k−1] by slicing a second equalization signal of the (k−1)th symbol using reference voltages, and may generate a second region value ER[k] by slicing a second equalization signal of the kth symbol using reference voltages. The first region value ER[k−1] may indicate the region to which the (k−1)th symbol value belongs, and the second region value ER[k] may indicate the region to which the kth symbol value belongs.

According to an example embodiment, the first slicer 611 may slice the second equalization signal into a plurality of voltage levels corresponding to the symbol values which the symbol according to the PAM method may have, respectively. The first slicer 611 may divide the regions to which the symbol value belongs into a lowermost region, intermediate regions, and an uppermost region.

For example, the first slicer 611 may slice the second equalization signal EQ2 using four voltage levels when the input signal is a PAM-4 signal. The first slicer 611 may divide the regions to which the symbol value belongs into the lowermost region, which has a range lower than the lowermost level among the four voltage levels, the intermediate regions between two adjacent voltage levels among the four voltage levels, and the uppermost region, which has a range higher than the uppermost level among the four voltage levels.

The first slicer 611 may predict the range of the symbol value in the intermediate regions as one of the two adjacent symbol values, may virtually determine the symbol value in the lowermost region as the lowermost symbol value, and may virtually determine the symbol value in the uppermost region as the uppermost symbol value. For example, the first slicer 611 may virtually determine the symbol value as “00” in the lowermost region, and may predict the symbol value as “00” or “01,” or “01” or “10,” or “10” or “11” in the intermediate regions. The first slicer 611 may virtually determine the symbol value as “11” in the uppermost region.

According to an example embodiment, there may be the case in which the kth symbol value or the (k−1)th symbol value may be actually determined by the first slicer 611 dividing the range to which the symbol value belongs into the lowermost region, the intermediate regions, and the uppermost region. When the kth symbol value or the (k−1)th symbol value is actually determined, the unit DFE circuit 600 may increase the probability that input signals having the same value are input to the chain multiplexer circuit 630 by controlling two input signals input to the chain multiplexer circuit 630 to have the same value.

The first delay element 612 may delay the first region value ER[k−1] of the (k−1)th symbol and may provide the first region value ER[k−1] to the first multiplexer circuit 613 at the timing of determining the symbol value D[k] of the kth symbol.

The first multiplexer circuit 613 may input weighted signals obtained by applying coefficient C1 to possible values of the (k−1)th symbol, may select weighted signals according to the value of the first region value ER[k−1] and may output the signals. For example, when the input signal is PAM-4, the first multiplexer circuit 613 may receive four weighted signals, and may output two weighted signals W[0] and W[1] using at least one signal selected according to the value of the first region value ER[k−1].

The symbols of PAM-4 signal, “00,” “01,” “10,” and “11,” may be normalized to the levels of “−3,” “−1,” “+1,” and “+3.” The first multiplexer circuit 613 may input weighted signals “+3*C1,” “+1*C1,” “−1*C1,” and “−3*C1” to compensate for influence of cases in which the (k−1)th symbol value D[k−1] is “00,” “01,” “10,” and “11,” respectively.

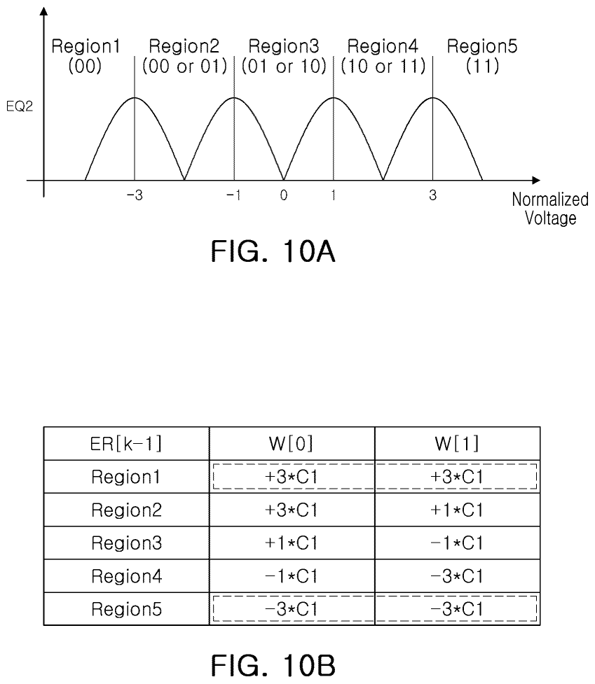

According to an example embodiment, the first multiplexer circuit 613 may effectively determine the (k−1)th symbol value as “00” when the value of the first region value ER[k−1] corresponds to the lowermost region, and may output the same signal “+3*C1” among the four weighted signals as two weighted signals W[0] and W[1], respectively. Similarly, the first multiplexer circuit 613 may effectively determine the (k−1)th symbol value as “11” when the first region value ER[k−1] corresponds to the uppermost region, and may output the same signal “−3*C1” among the four weighted signals as two weighted signals W[0] and W[1]. The first region value ER[k−1] and the weighted signals W[0] and W[1] output by the first multiplexer circuit 613 according to the first region value ER[k−1] may be described in greater detail with reference to FIG. 10A and FIG. 10B.

The adders 614 and 615 may output the values obtained by adding the first equalization signal EQ1[k] of the kth symbol to the two weighted signals W[0] and W[1] output by the first multiplexer circuit 613 as candidate signals CS[0] and CS[1]. When the same weighted signals are output by the first multiplexer circuit 613, the candidate signals CS[0] and CS[1] output by the adders 614 and 615 may also have the same level. When the candidate signals CS[0] and CS[1] have the same level, the input signals of the chain multiplexer circuit 630 may have the same values accordingly.

The slicing circuit 620 may include a plurality of slicers 621 and 622, a second multiplexer 623, and a plurality of restoration circuits 624 and 625. In an example embodiment, the slicing circuit 620 may further include delay circuits 626 and 627 to match the timing at which output signals are input to the chain multiplexer circuit 630.

The plurality of slicers 621 and 622 may slice the candidate signals CS[0] and CS[1] using a reference voltage Vref and may output slicing values SL[0] and SL[1]. According to an example embodiment, a plurality of slicers 621 and 622 may slice candidate signals CS[0] and CS[1] using a single reference voltage Vref, and the reference voltage Vref may be determined by a second region value ER[k].

According to an example embodiment, the second region value ER[k] may correspond to one of the lowermost region, the intermediate regions and the uppermost region. When the second region value ER[k] corresponds to the lowermost region, the kth symbol value D[k] may be effectively determined as the lowermost value “00,” and when the second region value ER[k] corresponds to the uppermost region, the kth symbol value D[k] may be effectively determined as the uppermost value “11.” When the second region value ER[k] corresponds to the intermediate regions, the kth symbol value D[k] may be predicted as one of the two adjacent values.

According to an example embodiment, the second multiplexer 623 may output one of a plurality of candidate reference voltages VLL, VL, VM, VH, and VHH as a reference voltage Vref according to the second region value ER[k].

The plurality of candidate reference voltages may include a lowermost reference voltage VLL, intermediate reference voltages VL, VM, and VH, and an uppermost reference voltage VHH. The intermediate reference voltages VL, VM, and VH may be reference voltages for determining a value of a candidate signal as one of two adjacent values. The lowermost reference voltage VLL and the uppermost reference voltage VHH may be reference voltages for actually outputting the determined symbol value as is.

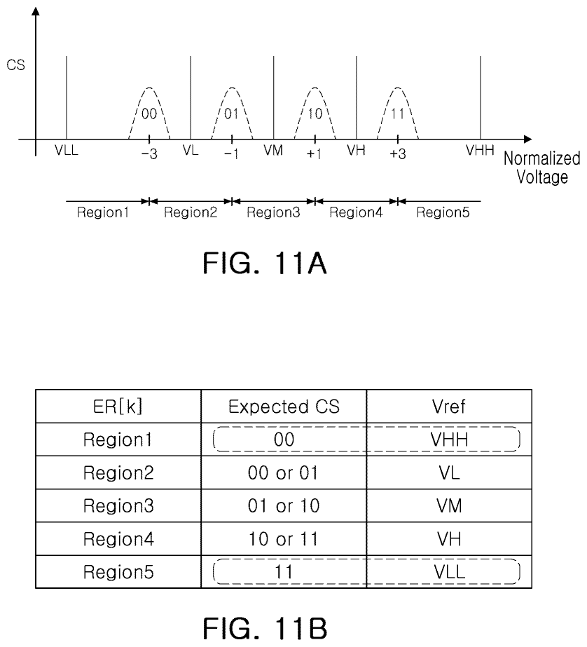

According to an example embodiment, when one of the intermediate reference voltages VL, VM, and VH is determined as the reference voltage, the slicing values SL[0] and SL[1] may have the same value or different values. When the lowermost reference voltage VLL or the uppermost reference voltage VHH is determined as the reference voltage, the slicing values SL[0] and SL[1] may have the same value. Accordingly, the probability that two input signals input to the chain multiplexer circuit 630 have the same value may increase. The reference voltage Vref according to the second region value ER[k] may be described in greater detail with reference to FIG. 11A and FIG. 11B.

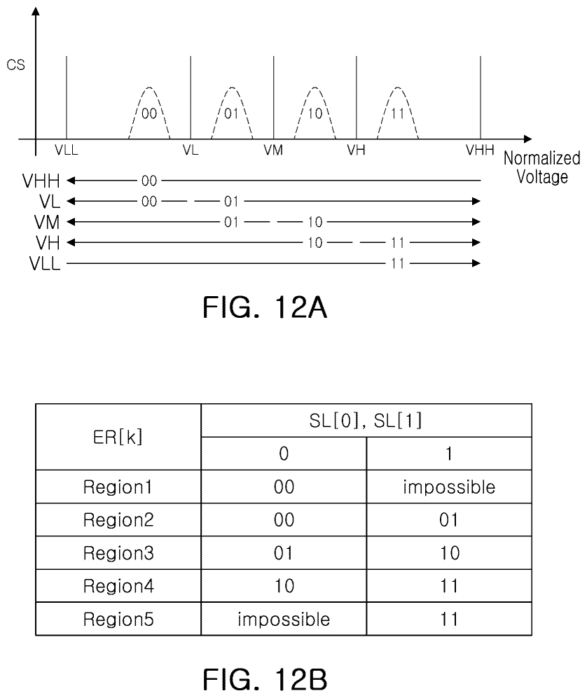

A plurality of restoration circuits 624 and 625 may restore slicing values SL[0] and SL[1] to candidate values CV[0] and CV[1] of the kth symbol. In the plurality of slicers 621 and 622, each of the slicing values SL[0] and SL[1] determined by a reference voltage may have a value of “0” or “1.” The plurality of restoration circuits 624 and 625 may restore slicing values SL[0] and SL[1] to candidate values CV[0] and CV[1] of one of “00,” “01,” “10,” and “11” based on the second region value ER[k]. The candidate values CV[0] and CV[1] according to the slicing values SL[0] and SL[1] and the second region value ER[k] may be described in greater detail with reference to FIG. 12A and FIG. 12B.

The chain multiplexer circuit 630 may be a 2:1 multiplexer circuit outputting one of the two candidate values CV[0] and CV[1] as the kth symbol value D[k]. The (k−1)th symbol value D[k−1] may be input to the chain multiplexer circuit 630 as a select signal, and the chain multiplexer circuit 630 may select one of the two candidate values CV[0] and CV[1] and output the value as the kth symbol value D[k]. For example, when different values, two candidate values CV[0] and CV[1], are input, the chain multiplexer circuit 630 may output one of the two candidate values CV[0] and CV[1] as the kth symbol value D[k] after the (k−1)th symbol value D[k−1] is determined.

As described with reference to FIGS. 6 and 7, when two candidate values CV[0] and CV[1] have the same value, the kth symbol value D[k] may be determined even before the (k−1)th symbol value D[k−1] is determined in the chain multiplexer circuit 630. In the chain multiplexer circuit 630, when two candidate values CV[0] and CV[1] have the same value, the accumulated delay may be resolved, and operation of outputting the kth symbol value D[k] by the chain multiplexer circuit 630 may be performed in parallel at a time point at which another multiplexer circuit operates among a plurality of chain multiplexer circuits included in the chain path.

According to an example embodiment, an uppermost region and a lowermost region may be introduced in a region to which the (k−1)th symbol value determined by the slicer 611 belongs, and a region to which the kth symbol value belongs. When the symbol value belongs to the uppermost region or the lowermost region, the symbol value may be actually determined, and the probability that the candidate values CV[0] and CV[1] input to the chain multiplexer circuit 630 have the same value may be increased.

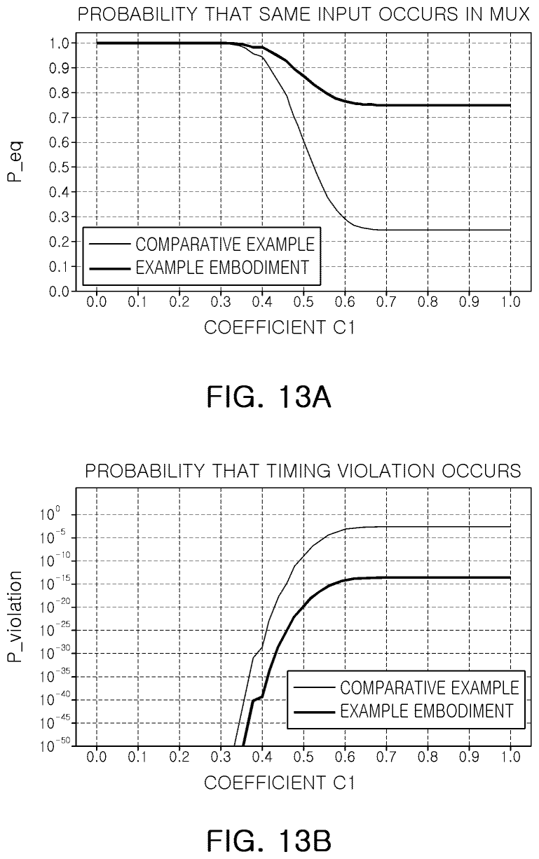

According to an example embodiment, the probability that the same values may be input to the chain multiplexer circuit 630 may increase, and the accumulated delay in the chain path may be alleviated. A specific example of the receiver in which timing violation due to the accumulated delay in the chain path statistically rarely occurs may be described with reference to FIGS. 13A and 13B.

FIGS. 10A and 10B are diagrams illustrating operation of a candidate generation circuit illustrated in FIG. 9. FIG. 10A is a graph illustrating a probability density function of the second equalization signal EQ2 according to a normalized voltage level. FIG. 10B is a table illustrating output signals W[0] and W[1] of a first multiplexer circuit 613 according to a first region value ER[k−1].

In the example in FIG. 10A, the symbol values “00,” “01,” “10” and “11” which the PAM-4 signal may have may be normalized to the levels of “−3,” “−1,” “+1” and “+3.” The normalization levels of the symbol values “00,” “01,” “10” and “11” are not limited to the example in FIG. 10A.

The second equalization signal EQ2 output by the second FFE circuit 522 described with reference to FIG. 8 may roughly indicate the value of the symbol. The second equalization signal EQ2 may have probability distribution having a bell shape and centered on the levels corresponding to the symbol values, “−3,” “−1,” “+1” and “+3.”

According to an example embodiment, a first slicer 611 as described with reference to FIG. 9 may slice a second equalization signal EQ2 using reference voltages corresponding to normalization levels of symbol values, and may determine a first region value ER[k−1] and a second region value ER[k].

In the example in FIG. 10A, a first region Region1 in which the second equalization signal EQ2 has a level lower than a normalization level “−3,” a second region Region2 in which the second equalization signal EQ2 has a level between normalization levels “−3” and “−1,” a third region Region3 in which the second equalization signal EQ2 has a level between normalization levels “−1” and “+1,” a fourth region Region4 in which the second equalization signal EQ2 has a level between normalization levels “+1” and “+3,” and a fifth region Region5 in which the second equalization signal EQ2 has a level higher than the normalization level “+3” may be defined.

When the second equalization signal EQ2 belongs to the second region Region2, the symbol value may be predicted as “00” or “01,” when the second equalization signal EQ2 belongs to the third region Region3, the symbol value may be predicted as “01” or “10,” and when the second equalization signal EQ2 belongs to the fourth region Region4, the symbol value may be predicted as “10” or “11.”

According to an example embodiment, the first region Region1 as the lowermost region and the fifth region Region5 as the uppermost region may be introduced. When the second equalization signal EQ2 belongs to the first region Region1, the symbol value may be determined as “00,” and when the second equalization signal EQ2 belongs to the fifth region Region5, the symbol value may be determined as “11.”

Referring to FIG. 10B, the weighted signals W[0] and W[1] output by the first multiplexer circuit 613 may be determined according to the first range ER[k−1] of the (k−1)th symbol value. When the first range ER[k−1] corresponds to the second region Region2, the (k−1)th symbol value may be predicted to be “00” or “01,” such that the weighted signal “+3*C1” to compensate for influence of the symbol value “00” and the weighted signal “+1*C1” to compensate for influence of the symbol value “01” may be output as the weighted signals W[0] and W[1]. Similarly, when the first range ER[k−1] corresponds to the third region Region3, the value of the first output signal W[0] may be “+1*C1,” and the value of the second weighted signal W[1] may be “−1*C1.” When the first range ER[k−1] corresponds to the fourth region Region4, the value of the first weighted signal W[0] may be “−1*C1,” and the value of the second weighted signal W[1] may be “−3*C1.”

According to an example embodiment, when the first range ER[k−1] corresponds to the lowermost region or the uppermost region, the multiplexer circuit 613 may output signals of the same value as the weighted signals W[0] and W[1]. When the first range ER[k−1] corresponds to the first region Region1, weighted signals W[0] and W[1] having a value of “+3*C1,” which is the uppermost level among the plurality of weighted signals, may be output to compensate for influence of the symbol value “00,” and when the first range ER[k−1] corresponds to the fifth region Region5, weighted signals W[0] and W[1] having a value of “−3*C1,” which is the lowermost level among the plurality of weighted signals, may be output to compensate for influence of the symbol value “11.”

FIGS. 11A and 11B are diagrams illustrating operation of second slicers illustrated in FIG. 9. FIG. 11A is a graph illustrating a probability density function of the candidate signal CS according to the normalized voltage level. FIG. 11B is a table illustrating the reference voltage Vref output by the second multiplexer circuit 623 according to the second region value ER[k].

In the example in FIG. 11A, the symbol values “00,” “01,” “10” and “11” that the PAM-4 signal may have may be normalized to the levels of “−3,” “−1,” “+1” and “+3.”

The candidate signals CS[0] and CS[1] (CS) output by the adders 614 and 615 described with reference to FIG. 9 may have probability distribution having a bell shape and centered on the levels corresponding to the symbol values, “−3,” “−1,” “+1” and “+3.” Since accuracy of the first FFE circuit 521 is higher than accuracy of the second FFE circuit 552, the probability distribution of the candidate signals CS in FIG. 11A may be more concentrated on the normalized levels “−3,” “−1,” “+1” and “+3” as compared to the probability distribution of the second equalization signal EQ2 in FIG. 10A.

According to an example embodiment, the second slicers 624 and 625 described with reference to FIG. 9 may slice the candidate signals CS based on a reference voltage Vref selected from a plurality of candidate reference voltages VLL, VL, VM, VH, and VHH. The plurality of candidate reference voltages may include a lowermost reference voltage VLL, intermediate reference voltages VL, VM, and VH and an uppermost reference voltage VHH.

Among the intermediate reference voltages, the first voltage VL may be a voltage for determining whether the candidate value is “00” or “01” when the second region value ER[k] corresponds to the second region Region2 and the candidate value of the candidate signal CS is predicted to be “00” or “01.” The first voltage VL may have a level between normalization levels “−3” and “−1,” for example, an intermediate level.

The second voltage VM may be a voltage for determining whether the candidate value of the candidate signal CS is “01” or “10” when the second region value ER[k] corresponds to the third region Region3. The second voltage VM may have a level between normalization levels “−1” and “+1,” for example, an intermediate level.

The third voltage VH may be a voltage for determining whether the second region value ER[k] is “10” or “11” when the second region value ER[k] corresponds to the fourth region Region4. The third voltage VH may have a level between normalization levels “+1” and “+3,” for example, an intermediate level.

According to an example embodiment, when the second region value ER[k] corresponds to the first region Region1, the uppermost reference voltage VHH may be selected as the reference voltage Vref. The uppermost reference voltage VHH may be determined as a voltage at a higher level than the voltage level at which the distribution of the candidate signal CS is formed. For example, the uppermost reference voltage VHH may be a voltage at a level higher than the normalized level “+3” corresponding to the symbol value “11.”

The lowermost reference voltage VLL may be a voltage configured to have a level higher than the distribution of the candidate signal CS and to output candidate signals CS[0] and CS[1] as the same value in a state in which the kth symbol value D[k] is determined as “00.”

According to an example embodiment, when the second region value ER[k] corresponds to the fifth region Region5, the lowermost reference voltage VLL may be selected as the reference voltage Vref. The lowermost reference voltage VLL may be a voltage for outputting candidate signals CS[0] and CS[1] as the same value when the kth symbol value D[k] is determined as “11.” The lowermost reference voltage VLL may be determined as a voltage at a lower level than the voltage level at which the distribution is formed. For example, the lowermost reference voltage VLL may be a voltage at a lower level than the normalized level “−3” corresponding to the symbol value “00.”

FIGS. 12A and 12B are diagrams illustrating operation of restoration circuits illustrated in FIG. 9. FIG. 12A is a graph illustrating a probability density function of a candidate signal CS according to a normalized voltage level. FIG. 12B is a table illustrating candidate values CV[0] and CV[1] determined by a second region value ER[k] and slicing values SL[0] and SL[1].

As described with reference to FIG. 11A, the candidate signal CS may have a certain probability distribution centered on the levels “−3,” “−1,” “+1” and “+3” corresponding to the symbol values.

Referring to FIGS. 12A and 12B, when the candidate signal CS is sliced using the uppermost reference voltage VHH, the slicing values SL[0] and SL[1] (SL) may have the value “0,” and the candidate value CV may be determined as “00” corresponding to the lowermost level. Accordingly, when the second region value ER[k] corresponds to the first region Region1, restoration circuits 624 and 625 described with reference to FIG. 9 may output the candidate value CV as “00.”

When the candidate signal CS is sliced using the first voltage VL, the slicing value SL may have a value of “0” or “1,” and when the slicing value SL is “0,” the candidate value CV may be determined as “00.” When the slicing value SL is “1,” the candidate value CV may be determined as “01.” Accordingly, when the second region value ER[k] corresponds to the second region Region2, the restoration circuits 624 and 625 may output the candidate value CV as “00” when the slicing value is “0,” and may output the candidate value CV as “01” when the slicing value is “1.”

Similarly, when the second region value ER[k] corresponds to the third region Region3, the restoration circuits 624 and 625 may output the candidate value CV as “01” when the slicing value is “0,” and may output the candidate value CV as “10” when the slicing value is “1.” When the second region value ER[k] corresponds to the fourth region Region4, the restoration circuits 624 and 625 may output the candidate value CV as “10” when the slicing value is “0,” and may output candidate value CV as “11” when the slicing value is “1.”

When the value of the second region ER[k] corresponds to the fifth region Region5, the slicing value SL may have the value of “1,” and the restoration circuits 624 and 625 may output the candidate value CV as “11” corresponding to the uppermost level.

According to an example embodiment, the second slicer 624 and 625 may slice the candidate signal CS[0] and CS[1] using a single reference voltage Vref determined according to the second region value ER[k], and may restore the candidate values CV according to the value of the second region ER[k]. Accordingly, the probability that the candidate values have the same value may be increased as compared to the case in which the slicers generate the candidate values using three reference voltages. Also, when the second region value ER[k] corresponds to the uppermost region or the lowermost region, the slicing value may be determined as a single value, such that the probability that the slicing values have the same value may be further increased.

In an example embodiment, the restoration circuits 624 and 625 may be implemented as a combinational logic circuit including several logic gates. That is, restoring the 1-bit values slicing values SL[0] and SL[1] to the PAM-4 symbol values candidate values CV[0] and CV[1] may cause almost no computational burden.

FIGS. 13A and 13B are diagrams illustrating reliability of a DFE circuit according to an example embodiment.

FIG. 13A is a graph illustrating a first probability P_eq, which is a probability that input signals having the same value may be input in a chain multiplexer circuit according to the value of coefficient C1, in a 1-tap DFE circuit for processing a PAM-4 signal according to an example embodiment and a comparative example different from the example embodiment. The example embodiment may correspond to a DFE circuit 523 included in a receiver 500 described with reference to FIGS. 8 and 9, and the comparative example may correspond to a partially unrolled DFE circuit 400 described with reference to FIG. 5.

The coefficient C1 may be determined by considering influence of a previous symbol, such as ISI, on a present symbol. As the value of coefficient C1 is smaller, the previous symbol value may be less reflected, and the value of coefficient C1 is larger, the previous symbol value may be more reflected. As the value of coefficient C1 is smaller, the candidate values input to the chain multiplexer circuit may be more affected by the present symbol value which may be commonly input, and accordingly, the first probability P_eq may increase. Conversely, as the value of coefficient C1 is larger, the input signals input to the chain multiplexer circuit may be more affected by the previous symbol value which may have different values, and accordingly, the first probability P_eq may decrease.

According to the comparative example, when the value of coefficient C1 is 0.4 or more, the first probability P_eq may decrease sharply, and when the value of coefficient C1 is 0.7 or more, the first probability P_eq may be simply about 0.25. Accordingly, depending on the value of coefficient C1, the probability that different values may be input to a plurality of consecutive chain multiplexer circuits in the chain path according to the comparative example may increase, and the delay may accumulate significantly in the chain path.

According to an example embodiment, when the value of coefficient C1 is 0.4 or more, the first probability P_eq may decrease, and even when the value of coefficient C1 is 0.7 or more, the first probability P_eq may be maintained at about 0.75. Accordingly, regardless of the value of coefficient C1, the accumulated delay in the chain path may be likely to be resolved, and timing violation may hardly occur.

FIG. 13B is a graph illustrating the second probability P_violation, which is the probability that timing violation occurs in the chain multiplexer circuit according to the value of coefficient C1 in a 1-tap DFE circuit for processing a PAM-4 signal according to an example embodiment and a comparative example different from the example embodiment.

More specifically, the graphs in FIG. 13B may indicate the second probability P_violation when the structure of the unit DFE circuits as described with reference to FIG. 9 is applied to the DFE circuit of the receiver based on the 56 Gb/s PAM-4 32-channel ADC/DSP using the 28 nm FDSOI process.

The clock frequency of the 56 Gb/s PAM-4 32-channel digital processing circuit DSP may be 875 MHz, and one cycle of the clock may be 1.14 ns. At least the operation of 32 unit DFE circuits may be completed in one cycle of the clock such that timing violation does not occur. Also, considering various factors such as the clock error, the timing margin may be determined to be 30%, and the receiver may target completing operation of 32 unit DFE circuits within 1.14 ns*0.7-0.80 ns.

The intrinsic delay of a 2:1 multiplexer circuit using a 28 nm FDSOI process may be up to 36 ps. When delays accumulate in consecutive 2:1 multiplexer circuits, up to 22 2:1 multiplexer circuits may complete operation within the target time of 800 ps.

According to an example embodiment, the second probability P_violation, that is, the probability that delays are accumulated in more than 22 2:1 multiplexer circuits, may be merely up to 1.7*10-14. Specifically, when the first probability P_eq that the same input signals may be input to the 2:1 multiplexer circuit and the number K of 2:1 multiplexer circuits which may operate within the target time are determined, the second probability P_violation may be determined according to equation 1 as below.

$${P}_{violation} = {( 1 - {P}_{eq} )}^{K + 1} \qquad [ Equation 1 ]$$

According to an example embodiment, even when K=22 and the first probability P_eq is the lowest at the level of 0.75, the second probability P_violation may be merely 1.7*10-14. According to the comparative example, when K=22 and the first probability P_eq is the lowest at the level of 0.25, the second probability P_violation may be determined to be about 10-3. FIG. 13B may illustrate the second probability P_violation according to coefficient C1 for each of the example embodiment and the comparative example.

The receiver may have a target BER by considering various causes of bit errors. For example, the receiver may allow a BER of 10-6 as the target BER. When the symbol values determined in the receiver include error bits within the target BER, the error bits may be corrected using an error correction technique in a device including the receiver.

According to the comparative example, the second probability P_violation may be higher than the target BER in the worst case, such that it may be difficult to directly apply the DFE circuit according to the comparative example to the receiver. For example, in order to apply the DFE circuit according to the comparative example to the receiver, the pipelining multiplexer structure or the look-ahead multiplexer structure, which is simply described with reference to FIG. 4, may need to be applied to the DFE circuit to comply with the time constraint. That is, the DFE circuit according to the comparative example may have an additional delay or may increase the circuit area of the receiver.

According to an example embodiment, the second probability P_violation may be 10-8 times the probability of the target BER, such that the receiver to which the DFE circuit according to the example embodiment is applied may be statistically reliable. Accordingly, the DFE circuit according to the example embodiment may comply with the time constraint without having an additional delay or increasing the circuit area of the receiver.

In the example in FIG. 13B, the DFE circuit of a 32-channel receiver is described as an example, but the DFE circuit according to an example embodiment may provide a statistically reliable receiver even when the number of channels of the receiver exceeds 32. Referring to equation 1 determining the second probability P_violation, the second probability P_violation may be related to the number K of multiplexer circuits which may operate consecutively within a target time determined based on one cycle of a clock according to the intrinsic delay of the multiplexer circuit, and may not be related to the number of channels.

For example, when the delay accumulation may be resolved statistically in 22 or fewer multiplexer circuits, the delay accumulation may occur in up to 22 consecutive multiplexer circuits regardless of whether the number of channels, that is, the number of multiplexer circuits included in the chain path, is 64 or 128, and the multiplexers in which the delay accumulation is resolved may operate in parallel with other multiplexer circuits. Accordingly, even in a receiver requiring a higher sampling rate, the time constraint may be met by performing a multichannel design using a DFE circuit according to an example embodiment.

The example embodiment is described with respect to a 1-tap DFE circuit for processing a PAM-4 signal as an example with reference to FIGS. 9 to 13B, but the example embodiments are not limited thereto.

The example embodiments may also be applied to a receiver receiving signals modulated according to various PAM schemes, such as PAM-8 and PAM-16. For example, when a unit DFE circuit 600 described with reference to FIG. 9 is applied to a receiver of a PAM-8 signal, the first slicer 611 may divide the range to which the kth symbol and (k−1)th symbol value belong into a lowermost region, seven intermediate regions, and an uppermost region using eight reference voltages. The time from one PAM symbol to the next PAM symbol is the symbol period.

Also, the example embodiments may also be applied to a 2-tap or more DFE circuit.

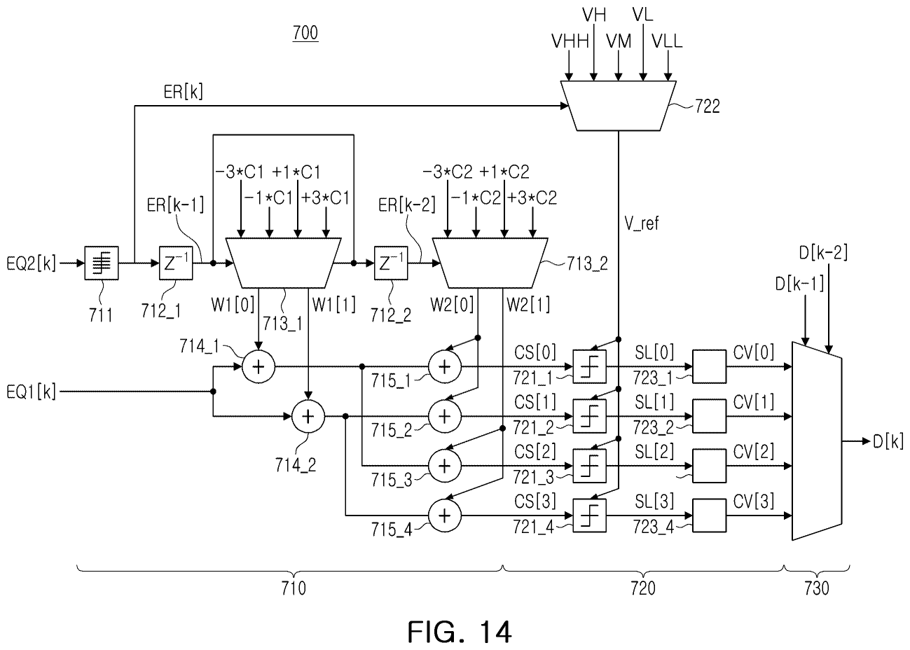

FIG. 14 is a diagram illustrating a unit DFE circuit according to an example embodiment.

The unit DFE circuit 700 in FIG. 14 may be a 2-tap DFE circuit for determining a symbol value D[k] of the kth symbol among N number of symbols using the (k−1)th symbol value D[k−1] and the (k−2)th symbol value D[k−2]. Each of the N number of symbols may be symbols according to PAM-4. The unit DFE circuit 700 may replace the unit DFE circuit 600 of the receiver 500 described with reference to FIG. 8.

The unit DFE circuit 700 may include a candidate decision circuit 710, a slicing circuit 720, and a chain multiplexer circuit 730. The plurality of candidate decision circuits and slicing circuits of the unit DFE circuits 700 included in the receiver may form a parallel stage, and the chain multiplexer circuits 730 may form a chain path.

The candidate decision circuit 710 may receive a first equalization signal EQ1 from the first FFE circuit 521 described with reference to FIG. 8, and may receive a second equalization signal EQ2 from the second FFE circuit 522.

The candidate decision circuit 710 may include a first slicer 711, a first delay element 712_1, a first multiplexer circuit 713_1, a second delay element 712_2, a second multiplexer circuit 713_2, first adders 714_1, 714_2: 714, and second adders 715_1, 715_2, 715_3, 715_4 (715).

The first slicer 711 may generate the first region value ER[k−2] by slicing the second equalization signal of the (k−2)th symbol using a plurality of voltage levels corresponding to the symbol values, may generate the second region value ER[k−1] by slicing the second equalization signal of the (k−1)th symbol, and may generate the third region value ER[k] by slicing the second equalization signal of the kth symbol using the plurality of voltage levels.

Similarly to the first slicer 611 described with reference to FIG. 9, the first slicer 711 may divide the region to which the symbol value belongs into the lowermost region, the intermediate regions, and the uppermost region. The first slicer 711 may practically determine the symbol value as the lowermost symbol value in the lowermost region, and may practically determine the symbol value as the uppermost symbol value in the uppermost region.

The first region value ER[k−2] may be delayed by the first delay element 712_1 and the second delay element 712_2 and may be input to the second multiplexer circuit 713_2. The second region value ER[k−1] may be delayed by the first delay element 712_1 and may be input to the first multiplexer circuit 713_1.

The first multiplexer circuit 713_1 may input weighted signals obtained by applying the first coefficient C1 to the possible (k−1)th symbol values, may select one or more weighted signals according to the value of the second region value ER[k−1], and may output the selected weighted signals as two weighted signals W1[0] and W1[1]. The first multiplexer circuit 713_1 may input weighted signals obtained by applying the second coefficient C2 to the possible (k−2)th symbol values, may select one or more weighted signals according to the value of the first region value ER[k−2], and may output the selected weighted signals as two weighted signals W2[0], W2[1].

According to an example embodiment, when the second region value ER[k−1] corresponds to the lowermost region, the first multiplexer circuit 713_1 may output the same weighted signal “+3*C1” having the uppermost level to two weighted signals W1[0], W1[1], respectively, to compensate for influence of the symbol value “00.” When the second region value ER[k−1] corresponds to the uppermost region, the first multiplexer circuit 713_1 may output the same weighted signal “−3*C1” having the lowermost level to two weighted signals W1[0], W1[1], respectively, to compensate for influence of the symbol value “11.”

Similarly, the second multiplexer circuit 713_2 may output the same weighted signal “+3*C2” having the uppermost level to two weighted signals W2[0], W2[1], respectively, when the first region value ER[k−2] corresponds to the lowermost region, and may output the same weighted signal “−3*C2” having the lowermost level to two weighted signals W2[0], W2[1], respectively, when the second region value ER[k−1] corresponds to the uppermost region.

The first and second adders 714 and 715 may generate four candidate signals by adding signals obtained by combining weighted signals W1[0], W1[1], W2[0], and W2[1] output by a plurality of multiplexer circuits 713_1 and 713_2 to the first equalization signal EQ1[k] of the kth symbol. Specifically, the first adders 714 may output two signals by adding output signals P1[0], P1[1] to the first equalization signal EQ1[k] of the kth symbol, respectively. The second adders 715 may output four candidate signals CS[0] and CS[1], CS[2], CS[3] (CS) by adding output signals P2[0], P2[1] to each of the two signals output by the first adders 714.

According to an example embodiment, the probability that four candidate signals CS have the same value may be increased by outputting the same output signals from the first multiplexer circuit 613_1 and the second multiplexer circuit 613_2 according to the region to which the (k−1)th symbol value D[k−1] belongs and the region to which the (k−2)th symbol value D[k−2] belongs.

The slicing circuit 720 may include a plurality of second slicers 721_1, 721_2, 721_3, and 721_4 (721), a second multiplexer 722, and a plurality of restoration circuits 723_1, 723_2, 723_3, and 723_4 (723).

The plurality of second slicers 721 may slice candidate signals CS using a reference voltage Vref, and may output slicing values SL[0], SL[1], SL[2], and SL[3] (SL). The plurality of second slicers 721 may slice candidate signals CS using a reference voltage Vref, and the reference voltage Vref may be determined by a third region value ER[k].

A second multiplexer 722 may output one of the plurality of candidate reference voltages VLL, VL, VM, VH, and VHH as a reference voltage Vref according to the third region value ER[k]. According to an example embodiment, the second multiplexer 722 may output the uppermost reference voltage VHH as the reference voltage Vref when the third region value ER[k] corresponds to the lowermost region, and may output the lowermost reference voltage VLL as the reference voltage Vref when the third region value ER[k] corresponds to the uppermost region.

The lowermost reference voltage VLL and the uppermost reference voltage VHH may be reference voltages for outputting the determined symbol value as is. When the lowermost reference voltage VLL or the uppermost reference voltage VHH is determined as the reference voltage, the slicing values SL may have the same value. Accordingly, the probability that two input signals input to the chain multiplexer circuit 730 have the same value may increase

The plurality of restoration circuits 723 may restore the slicing values SL to the candidate values CV[0], CV[1], CV[2], and CV[3] (CV) of the kth symbol. The plurality of restoration circuits 723 may restore the slicing values SL to one of the candidate values CV among “00,” “01,” “10,” and “11” based on the third region value ER[k].

The chain multiplexer circuit 730 may be a 4:1 multiplexer circuit for outputting one of the four candidate values CV as the kth symbol value D[k] when the (k−2)th symbol value D[k−2] and the (k−1)th symbol value D[k−1] are determined.

Similarly to the example described with reference to FIGS. 6 and 7, in a 4:1 multiplexer circuit, when four candidate values CV have the same value, the kth symbol value D[k] may be determined before the (k−2)th symbol value D[k−2] and (k−1)th symbol value D[k−1] are determined.

According to an example embodiment, an uppermost region and a lowermost region may be introduced in the region of the (k−2)th symbol value, the region of the (k−1)th symbol value, and the region of the kth symbol value determined by the slicer 711. When the symbol value belongs to the uppermost region or the lowermost region, the symbol value may be determined, and the probability that the candidate values CV input to the chain multiplexer circuit 730 have the same values may be increased. Accordingly, the accumulated delay in the chain path may be alleviated.

Comparing FIG. 9 with FIG. 14, the chain multiplexer circuit 730 in FIG. 14 may be a 4:1 multiplexer circuit, such that intrinsic delay may be higher than the chain multiplexer circuit 630 in FIG. 9. Accordingly, due to the target time determined based on the clock cycle and the intrinsic delay of the multiplexer circuit, the number of multiplexer circuits which may continuously complete operations within the target time may be less in FIG. 14 than in FIG. 9.

Even when four candidate values CV are input to the chain multiplexer circuit 730 and two candidate values CV are input to the chain multiplexer circuit 630, there may be almost no difference between the probability that the same candidate values may be input to the chain multiplexer circuit 730 and the probability that the same candidate values may be input to the chain multiplexer circuit 630.

Influence of the (k−2)th symbol on the kth symbol may be smaller than influence of the (k−1)th symbol on the kth symbol. Accordingly, the second coefficient C2 in which influence of the (k−2)th symbol on the kth symbol is reflected may be smaller than the first coefficient C1 in which influence of the (k−1)th symbol on the kth symbol is reflected.

As illustrated in the graph in FIG. 13A, in a DFE circuit according to an example embodiment, when the coefficient is less than 0.4, the first probability P_eq, which is the probability that input signals having the same value may be input, may be close to 1. Similarly, in the case of the second coefficient C2, when the second coefficient C2 may be determined to be less than 0.4, the second coefficient may rarely affect the first probability P_eq. That is, in the case of a 2-tap DFE circuit, the number of candidate values input to the multiplexer circuit may increase from 2 to 4 as compared to a 1-tap DFE circuit, but the probability that 4 candidate values have the same value may not be significantly reduced as compared to the probability that 2 candidate values have the same value.

According to an example embodiment, in a DFE circuit having a chain path including multiplexer circuits, an uppermost region and a lowermost region to which a symbol value belongs may be introduced according to the level of an equalization signal from an FFE circuit for roughly predicting a symbol value. When the level of the equalization signal belongs to the uppermost region or the lowermost region, the symbol value may be determined. When the present symbol value or the previous symbol value is determined in each unit DFE circuit, by controlling the same candidate values are input to the multiplexer circuit, the probability that the accumulated delay in the chain path is resolved may be increased. When the probability that the accumulated delay of the multiplexer circuits of the chain path is resolved increases, the time constraint may be statistically overcome. Accordingly, a DFE circuit and a receiver having reliability for the time constraint may be provided.

According to the aforementioned example embodiments, a DFE circuit may increase the probability that the 2:1 multiplexer may generate an output signal without waiting for an output of the previous 2:1 multiplexer by increasing the probability that signals of the same value are input to the 2:1 multiplexer included in the chain path. In other words, the probability that delay accumulation in the chain path of the DFE circuit is resolved may increase, and the time constraint may be statistically overcome.

While the example embodiments have been illustrated and described above, it will be configured as apparent to those skilled in the art that modifications and variations could be made without departing from the scope of the present disclosure as defined by the appended claims.

What is claimed is:

1. A digital processing circuit comprising:
a first feed forward equalizer (FFE) circuit configured to equalize a digital signal comprising a plurality of symbols according to a pulse amplitude modulation (PAM) method and to output a first equalization signal;
a second FFE circuit configured to equalize the digital signal and to output a second equalization signal; and
a decision feedback equalization (DFE) circuit,
wherein the DFE circuit comprises:
a candidate generation circuit configured to determine a first region to which a previous symbol among the plurality of symbols belongs and a second region to which a present symbol among the plurality of symbols belongs by slicing the second equalization signal into a plurality of voltage levels corresponding to symbol values, and to generate two candidate signals by adding at least one signal selected based on the first region among a plurality of weighted signals determined by applying a coefficient to possible values of the previous symbol to the first equalization signal of the present symbol;
a slicing circuit configured to generate two slicing values by slicing the two candidate signals with respect to a reference voltage determined based on the second region among a plurality of candidate reference voltages, and to restore the two slicing values to candidate values of the present symbol based on the second region; and
a chain multiplexer circuit configured to receive a symbol value of the previous symbol as a select signal, to select one of candidate values of the present symbol and to output the value as a symbol value of the present symbol, and
wherein the candidate generation circuit is further configured to:
based on the first region being a lowermost region in a range lower than a lowermost voltage level among the plurality of voltage levels, generate the two candidate signals having a same voltage level using a first signal having an uppermost level among the plurality of weighted signals, or
based on the first region being an uppermost region having a voltage level higher than an uppermost voltage level among the plurality of voltage levels, generate the two candidate signals having the same voltage level using a second signal having a lowermost voltage level among the plurality of weighted signals.

2. The digital processing circuit of claim 1, wherein the plurality of candidate reference voltages comprise a lowermost reference voltage having a voltage level lower than the plurality of voltage levels and an uppermost reference voltage having a voltage level higher than the plurality of voltage levels,
wherein, based on the second region being the lowermost region, the slicing circuit is further configured to determine the reference voltage as the uppermost reference voltage, and
wherein, based on the second region being the uppermost region, the slicing circuit is further configured to determine the reference voltage as the lowermost reference voltage.

3. The digital processing circuit of claim 2, wherein the chain multiplexer circuit is further configured to:
based on a same value being input as the candidate values of the present symbol, output the same value as the symbol value of the present symbol regardless of whether the symbol value of the previous symbol is determined, and
based on different values being input as the candidate values of the present symbol, output the one of candidate values of the present symbol as the symbol value of the present symbol after the symbol value of the previous symbol is determined.

4. The digital processing circuit of claim 2, wherein the candidate generation circuit is further configured to, based on the first region being an intermediate region between two adjacent voltage levels among the plurality of voltage levels, generate two candidate signals having different levels using two signals corresponding to the first region among the plurality of weighted signals.

5. The digital processing circuit of claim 2, wherein the candidate generation circuit comprises:
a first slicer configured to determine the first region and the second region by slicing the second equalization signal into the plurality of voltage levels;
a first multiplexer circuit configured to output at least one signal selected from among the plurality of weighted signals according to a value of the first region as two weighted signals, and
adders configured to output the two candidate signals by adding each of the two weighted signals to the first equalization signal of the present symbol.

6. The digital processing circuit of claim 2, wherein, based on the second region being an intermediate region between two adjacent voltage levels among the plurality of voltage levels, the slicing circuit is further configured to determine the reference voltage as having a voltage level between the two adjacent voltage levels.

7. The digital processing circuit of claim 2, wherein, based on the second region being an intermediate region between two adjacent voltage levels among the plurality of voltage levels, the slicing circuit is further configured to determine the reference voltage as having intermediate level between the two adjacent voltage levels.

8. The digital processing circuit of claim 2, wherein the slicing circuit comprises:
second slicers configured to slice the two candidate signals by the reference voltage and to correspondingly output the two slicing values, and
restoration circuits configured to restore the two slicing values to the candidate values of the present symbol based on the second region, and
wherein each of the restoration circuits is configured to:
based on the second region being the lowermost region, determine a candidate value of the present symbol as a symbol value corresponding to the lowermost voltage level among the plurality of voltage levels, and
based on the second region being the uppermost region, determine the candidate values of the present symbol as a symbol value corresponding to an uppermost voltage level among the plurality of voltage levels.

9. The digital processing circuit of claim 8, wherein each of the restoration circuits is further configured to, based on the second region being an intermediate region between two adjacent voltage levels among the plurality of voltage levels, determine the candidate value of the present symbol by selecting one of adjacent symbol values corresponding to the second region based on the received slicing value.

10. The digital processing circuit of claim 1, wherein a first number of taps in the first FFE circuit is greater than a second number of taps in the second FFE circuit.

11. The digital processing circuit of claim 1, wherein the first FFE circuit and the second FFE circuit operate in parallel.

12. A digital processing circuit comprising:
a first feed forward equalizer (FFE) circuit configured to equalize a digital signal comprising a plurality of symbols according to a pulse amplitude modulation (PAM) method and to output a first equalization signal;
a second FFE circuit configured to equalize the digital signal and to output a second equalization signal; and
an M-tap decision feedback equalization (DFE) circuit configured to use M previous symbols to equalize a present symbol among the plurality of symbols, where M is a natural number,
wherein the DFE circuit comprises:
a first slicer configured to determine M first regions to which M previous symbols among the plurality of symbols belong and a second region to which the present symbol among the plurality of symbols belongs, respectively, by slicing the second equalization signal into a plurality of voltage levels corresponding to symbol values, respectively;
M first multiplexer circuits configured to receive a plurality of weighted signals generated by applying a coefficient corresponding to a corresponding symbol among the M previous symbols to possible values of the corresponding symbol, and to output one or more signals selected based on a corresponding first region among the M first regions as two weighted signals,
adders configured to generate 2M candidate signals by adding signals obtained by combining weighted signals output by the M first multiplexer circuits to the first equalization signal of the present symbol;
a slicing circuit configured to generate slicing values by slicing the candidate signals by a reference voltage determined based on the second region among a plurality of candidate reference voltages, and to restore the slicing values to candidate values of the present symbol based on the second region; and
a chain multiplexer circuit configured to receive symbol values of the M previous symbols as select signals and to output one of the candidate values of the present symbol as a symbol value of the present symbol, and
wherein each of the M first multiplexer circuits is further configured to:
based on the corresponding first region being a lowermost region in a range lower than a lowermost voltage level among the plurality of voltage levels, generate the two candidate signals using a first signal having an uppermost level among the plurality of weighted signals, or
based on the corresponding first region being an uppermost region higher than an uppermost voltage level among the plurality of voltage levels, generate the two candidate signals using a second signal having a lowermost level among the plurality of weighted signals.

13. The digital processing circuit of claim 12, wherein the plurality of candidate reference voltages comprise a lowermost reference voltage having a voltage level lower than the plurality of voltage levels and an uppermost reference voltage having a voltage level higher than the plurality of voltage levels,
wherein, based on the second region being the lowermost region, the slicing circuit is further configured to determine the reference voltage as the uppermost reference voltage, and
wherein, based on the second region being the uppermost region, the slicing circuit is further configured to determine the reference voltage as the lowermost reference voltage.

14. The digital processing circuit of claim 13, wherein the chain multiplexer circuit is further configured to, based on a same value being input as a candidate value of the present symbol, output the same value as the symbol value of the present symbol regardless of whether the symbol value of the M previous symbols is determined, and
wherein, based on different values being input as the candidate values of the present symbol, the chain multiplexer circuit is further configured to output one of the candidate values as a present symbol after symbol values of the M previous symbols are determined.

15. A receiver comprising:
an analog-to-digital converter (ADC) circuit configured to generate a digital signal comprising a plurality of symbols of a received signal modulated according to a pulse amplitude modulation (PAM) method; and
a digital processing circuit configured to receive the plurality of symbols and to output symbol values of the plurality of symbols,
wherein the digital processing circuit comprises:
a first feed forward equalizer (FFE) circuit configured to output a first equalization signal of the plurality of symbols;
a second FFE circuit configured to output a second equalization signal of the plurality of symbols; and
a decision feedback equalization (DFE) circuit configured to output N symbol values by processing N symbols in parallel among the plurality of symbols, where N is a natural number,
wherein the DFE circuit comprises:
a parallel stage comprising N circuits configured to determine a first region to which a previous symbol among the N symbols belongs and a second region to which a corresponding symbol among the N symbols belongs by slicing the second equalization signal into a plurality of voltage levels corresponding to symbol values to generate a plurality of candidate values using the first equalization signal of the first region, the second region and the corresponding symbol; and
a chain path comprising N chain multiplexer circuits configured to receive a symbol value of the previous symbol as a select signal, and to output one of the plurality of candidate values as a symbol value of the corresponding symbol, and
wherein each of the N circuits is configured to, based on the first region or the second region being a lowermost region in a range lower than a lowermost voltage level among the plurality of voltage levels or an uppermost region higher than an uppermost voltage level among the plurality of voltage levels, input the plurality of candidate values having the same value to a corresponding multiplexer circuit among the N multiplexer circuits.

16. The receiver of claim 15, wherein each of the N chain multiplexer circuits is further configured to:
based on a same value being input as candidate values of the corresponding symbol, output the same value as the symbol value of the corresponding symbol regardless of whether a symbol value of the previous symbol is determined, and
based on different values being input as the candidate values of the corresponding symbol, output one of candidate values of the corresponding symbol as the symbol value of a present symbol after the symbol value of the previous symbol is determined.

17. The receiver of claim 16, wherein the ADC circuit is further configured to generate the digital signal by sampling the received signal using a multi-phase clock signal including N clock signals having different phases.

18. The receiver of claim 17, wherein each of the N chain multiplexer circuits has an intrinsic delay greater than a (1/N) cycle of a clock signal associated with the receiver, and the clock signal has a period corresponding to N symbol periods.

19. The receiver of claim 18, wherein a number of chain multiplexer circuits is N, and N is greater than a value obtained by dividing a target time determined based on a single cycle of the clock signal by the intrinsic delay of a chain multiplexer circuit of the N chain multiplexer circuits.

20. The receiver of claim 17, wherein a first chain multiplexer circuit among the N chain multiplexer circuits is configured to, based on the same value being input as a candidate value of the present symbol, perform an operation of outputting the same value regardless of whether a symbol value of the previous symbol is determined in parallel at a time point at which at least one other multiplexer circuit among the N chain multiplexer circuits operates.
